(19) United States
(12) Patent Application Publication
(10) Pub. No.: US 2025/0157964 A1
(43) Pub. Date: May 15, 2025

(54) BONDING STRUCTURES FOR HIGH-DENSITY METAL-TO-METAL BONDING AND METHODS FOR FORMING THE SAME

(71) Applicant: WESTERN DIGITAL TECHNOLOGIES, INC.,, SAN JOSE, CA (US)

(72) Inventors: Adarsh RAJASHEKHAR, San Jose, CA (US); Senaka KANAKAMEDALA, San Jose, CA (US); Keisuke IZUMI, Yokkaichi (JP); Johann ALSMEIER, San Jose, CA (US)

(21) Appl. No.: 18/509,035

(22) Filed: Nov. 14, 2023

(51) Int. Cl. H01L 23/00; H01L 23/522; H01L 23/528; H01L 23/532; H01L 25/065

(52) U.S. Cl. CPC H01L 24/08; H01L 23/5226; H01L 23/5283; H01L 23/53238; H01L 23/53295; H01L 24/03; H01L 24/05; H01L 24/80; H01L 25/0657; H01L 2224/03614; H01L 2224/03622; H01L 2224/05147; H01L 2224/08145; H01L 2224/80357; H01L 2224/80895; H01L 2225/06541; H01L 2924/1431; H01L 2924/1434

(57) ABSTRACT

A bonded assembly of a first semiconductor die and a second semiconductor die is provided. The first semiconductor die includes first dielectric material layers located on first semiconductor devices, first metal interconnect structures embedded in the first dielectric material layers and electrically connected to the first semiconductor devices, and a first bonding-level dielectric layer located on the first dielectric material layers and embedding first metallic bonding structures that are electrically connected to a respective one of the first metal interconnect structures, and further embedding first dummy metallic bonding structures having a lesser vertical extent than the first metallic bonding structures and electrically isolated from the first metal interconnect structures.

### FIELD

The present disclosure relates generally to the field of semiconductor devices, and particularly to semiconductor dies including bonding structures for high-density metal-to-metal bonding and methods for forming the same.

### BACKGROUND

Metal-to-metal bonding may be used to provide electrical connection between a mating pair of semiconductor dies having opposing bonding pads. However, methods of making bonding pads typically utilize a number of steps.

### SUMMARY

According to an aspect of the present disclosure, a method of forming a semiconductor structure is provided. The method comprises: forming first semiconductor devices on a first substrate; forming first dielectric material layers embedding first metal interconnect structures over the first semiconductor devices, wherein the first metal interconnect structures are electrically connected to the first semiconductor devices; forming a first bonding-level dielectric layer comprising a layer stack including a first silicate glass layer and a first dielectric bonding material layer over the first dielectric material layers; forming via cavities through the first dielectric bonding material layer and the first silicate glass layer; converting the via cavities into integrated pad-and-via cavities by performing a selective etch process that etches a material of the first dielectric bonding material layer selective to a material of the first silicate glass layer; and forming first integrated pad-and-via bonding structures comprising a respective metallic via portion that is laterally surrounded by the first silicate glass layer and a respective metallic pad portion that is laterally surrounded by the first dielectric bonding material layer in the via cavities.

According to another aspect of the present disclosure, a bonded assembly of a first semiconductor die and a second semiconductor die is provided. The first semiconductor die comprises: first dielectric material layers located on first semiconductor devices; first metal interconnect structures embedded in the first dielectric material layers and electrically connected to the first semiconductor devices; a first bonding-level dielectric layer located on the first dielectric material layers and comprising a layer stack including a first silicate glass layer and a first silicon carbide nitride layer; and first integrated pad-and-via bonding structures comprising a respective metallic via portion that is laterally surrounded by the first silicate glass layer and a respective metallic pad portion that is laterally surrounded by the first silicon carbide nitride layer and bonded to a respective second metallic bonding structure of the second semiconductor die through metal-to-metal bonding.

According to yet another aspect of the present disclosure, a bonded assembly of a first semiconductor die and a second semiconductor die is provided. The first semiconductor die comprises: first dielectric material layers located on first semiconductor devices; first metal interconnect structures embedded in the first dielectric material layers and electrically connected to the first semiconductor devices; and a first bonding-level dielectric layer located on the first dielectric material layers and embedding first metallic bonding structures that are electrically connected to a respective one of the first metal interconnect structures, and further embedding first dummy metallic bonding structures having a lesser vertical extent than the first metallic bonding structures and electrically isolated from the first metal interconnect structures.

According to still another aspect of the present disclosure, a method of forming a semiconductor structure is provided. The method comprises: forming first semiconductor devices on a first substrate; forming first metal interconnect structures embedded in first dielectric material layers over the first semiconductor devices; forming a first bonding-level dielectric layer over the first dielectric material layers; forming via cavities and dummy via cavities in the first bonding-level dielectric layer, wherein the via cavities vertically extend from a topmost surface of the bonding-level dielectric layer to a bottommost surface of the bonding-level dielectric layer, and the dummy via cavities have a lesser vertical extent than the via cavities; and forming first metallic bonding structures and first dummy metallic bonding structures, wherein each of the first metallic bonding structures is formed in a respective first volume that comprises an entirety of a volume of a respective one via cavities, and each of the first dummy metallic bonding structures is formed in a respective second volume that comprises an entirety of a volume of a respective subset of the dummy via cavities.

According to another aspect of the present disclosure, a bonded assembly of a first semiconductor die and a second semiconductor die is provided. The first semiconductor die comprises: first dielectric material layers located on first semiconductor devices; first metal interconnect structures embedded in the first dielectric material layers and electrically connected to the first semiconductor devices; and a first bonding-level dielectric layer located on the first dielectric material layers and embedding a first metallic bonding structure that is electrically connected to one of the first metal interconnect structures, and further embedding a first dummy metallic bonding structure having a lesser vertical extent than the first metallic bonding structure and electrically isolated from the first metal interconnect structures. The first metallic bonding structures have a different vertical cross-sectional shape than the first dummy metallic bonding structures.

According to further aspect of the present disclosure, a method of forming a semiconductor structure comprises forming first semiconductor devices over, on or in a first substrate; forming first metal interconnect structures embedded in first dielectric material layers over the first semiconductor devices; forming a first bonding-level dielectric layer over the first dielectric material layers; simultaneously forming a first via cavity and a first dummy via cavity in the first bonding-level dielectric layer, the first dummy via cavity having a lesser lateral extent and a lesser depth than the first via cavity; and simultaneously forming a first metallic bonding structure in the first via cavity and forming a first dummy metallic bonding structure in the first dummy via cavity to form a first semiconductor die.

### BRIEF DESCRIPTION OF THE DRAWINGS

FIGS. 1A, 1B, 1D, 1F, 1G, and 1H are sequential vertical cross-sectional views of a first exemplary structure during formation of a bonded assembly of a first semiconductor die and a second semiconductor die according to an embodiment of the present disclosure. FIG. 1C is a top-down view of the first exemplary structure of FIG. 1B. The vertical plane B-B′ in FIG. 1C is the cut plane of the vertical cross-sectional view of FIG. 1B. FIG. 1E is a top-down view of the first exemplary structure of FIG. 1D. The vertical plane D-D′ in FIG. 1E is the cut plane of the vertical cross-sectional view of FIG. 1D. FIG. 1F is a vertical cross-sectional view of the second semiconductor die prior to bonding with the first semiconductor die.

FIGS. 2A-2C are sequential vertical cross-sectional views of a second exemplary structure during formation of the first semiconductor die according to an embodiment of the present disclosure.

FIG. 3 is a vertical cross-sectional view of a third exemplary structure according to an embodiment of the present disclosure.

FIG. 4 is a vertical cross-sectional view of a fourth exemplary structure according to an embodiment of the present disclosure.

FIGS. 5A, 5D, 5E, 5F, 5I, and 5L are sequential vertical cross-sectional views of a fifth exemplary structure during formation of a bonded assembly of a first semiconductor die and a second semiconductor die according to an embodiment of the present disclosure. FIGS. 5B and 5C are top-down views of two configurations of the fifth semiconductor die illustrated in FIG. 5A. The vertical planes A-A′ in FIGS. 5B and 5C are the cut plane of the vertical cross-sectional view of FIG. 5A. FIGS. 5G and 5H are top-down views of two configurations of the fifth semiconductor die illustrated in FIG. 5F. The vertical planes F-F in FIGS. 5G and 5H are the cut plane of the vertical cross-sectional view of FIG. 5F. FIG. 5J is a top-down view of the fifth exemplary structure of FIG. 5I. The vertical plane I-I′ in FIG. 5J is the cut plane of the vertical cross-sectional view of FIG. 5I. FIG. 5K is a vertical cross-sectional view of the second semiconductor die prior to bonding with the first semiconductor die.

FIGS. 6A and 6B are sequential vertical cross-sectional views of a sixth exemplary structure during formation of the first semiconductor die according to an embodiment of the present disclosure.

FIGS. 7A, 7D, 7E, 7F, and 7G are sequential vertical cross-sectional views of a seventh exemplary structure during formation of a bonded assembly of a first semiconductor die and a second semiconductor die according to an embodiment of the present disclosure. FIGS. 7B and 7C are top-down views of two configurations of the seventh exemplary structure of FIG. 7A. The vertical planes A-A′ in FIGS. 7B and 7C are the cut planes of the vertical cross-sectional view of FIG. 7A.

FIGS. 8A, 8C, 8D, 8E, 8F, 8G, and 8H are sequential vertical cross-sectional views of an eighth exemplary structure during formation of a bonded assembly of a first semiconductor die and a second semiconductor die according to an embodiment of the present disclosure. FIG. 8B is a top-down view of the eighth exemplary structure of FIG. 8A. The vertical plane A-A′ in FIG. 8B is the cut plane of the vertical cross-sectional view of FIG. 8A.

FIGS. 9A, 9B, 9C, 9D, and 9E are sequential vertical cross-sectional views of a ninth exemplary structure during formation of a bonded assembly of a first semiconductor die and a second semiconductor die according to an embodiment of the present disclosure.

FIGS. 10A, 10D, and 10G are sequential vertical cross-sectional views of a tenth exemplary structure during formation of a bonded assembly of a first semiconductor die and a second semiconductor die according to an embodiment of the present disclosure. FIGS. 10B and 10C are top-down views of two configurations of the tenth semiconductor die illustrated in FIG. 10A. The vertical planes A-A′ in FIGS. 10B and 10C are the cut plane of the vertical cross-sectional view of FIG. 10A. FIGS. 10E and 10G are top-down views of two configurations of the tenth semiconductor die illustrated in FIG. 10D. The vertical planes D-D′ in FIGS. 10E and 10F are the cut plane of the vertical cross-sectional view of FIG. 10B.

### DETAILED DESCRIPTION

The embodiments of the present disclosure are directed to semiconductor dies including bonding structures for high-density metal-to-metal bonding and methods for forming the same, of which various aspects are now described in detail. The embodiments of the present disclosure can be employed to form semiconductor devices, such as three-dimensional memory devices comprising a plurality of memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or from each other, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the first continuous structure. For example, a layer may be located between any pair of horizontal planes between, or at, a top surface and a bottom surface of the first continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

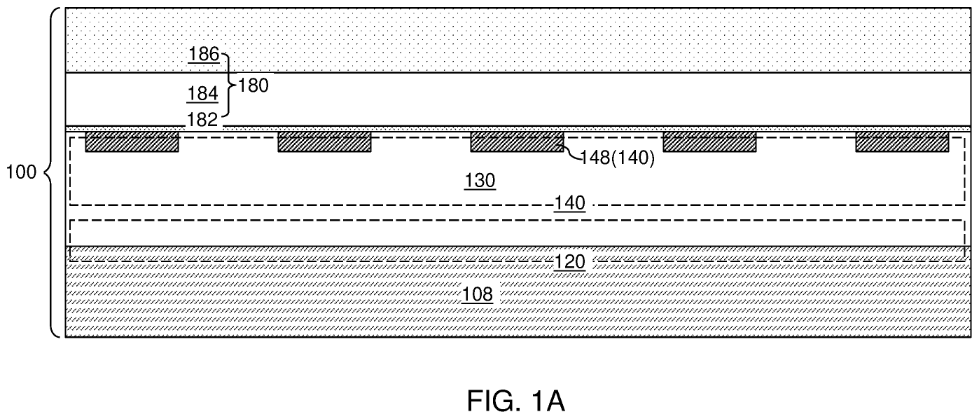

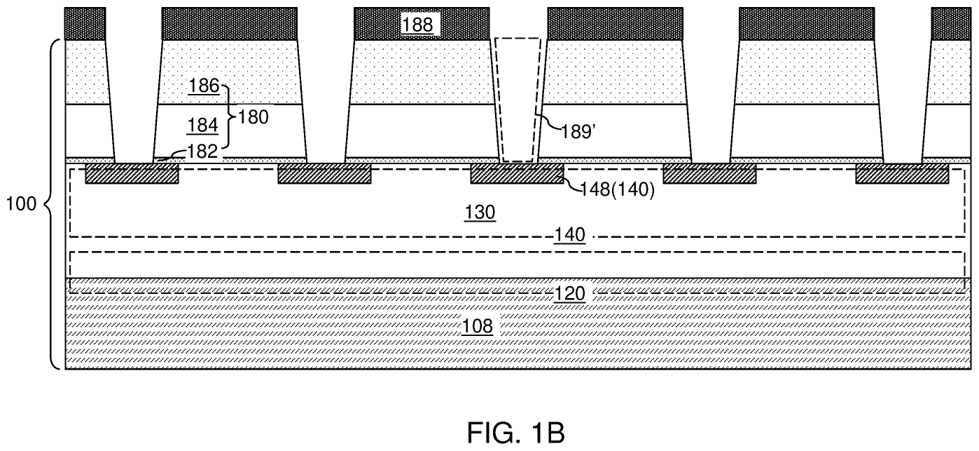

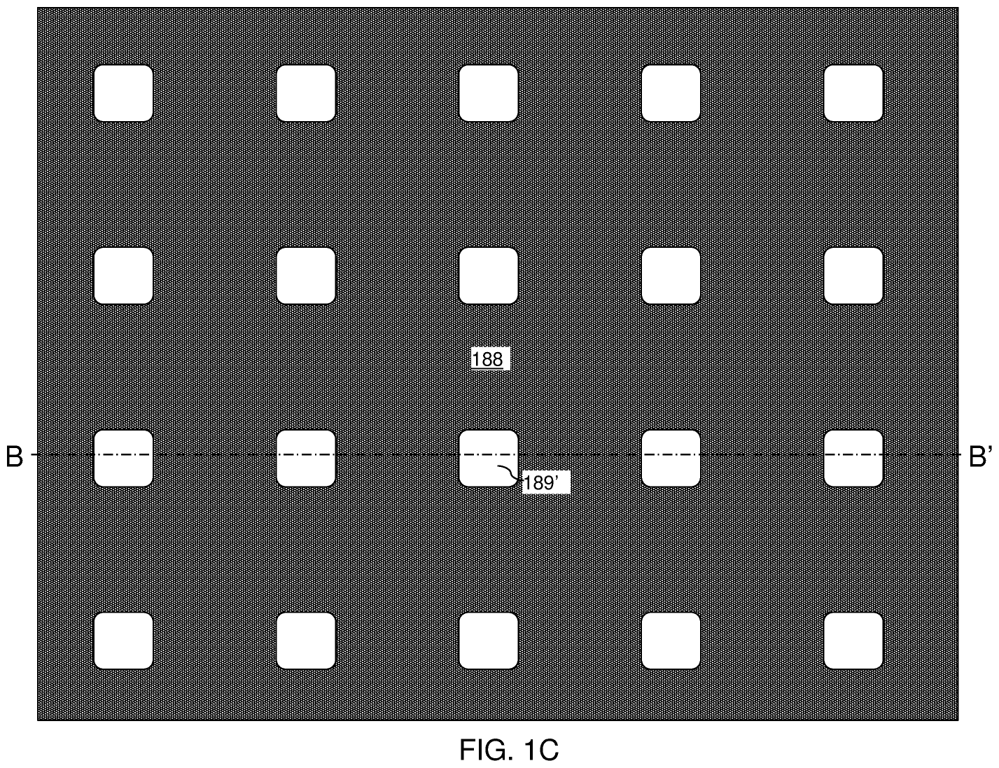

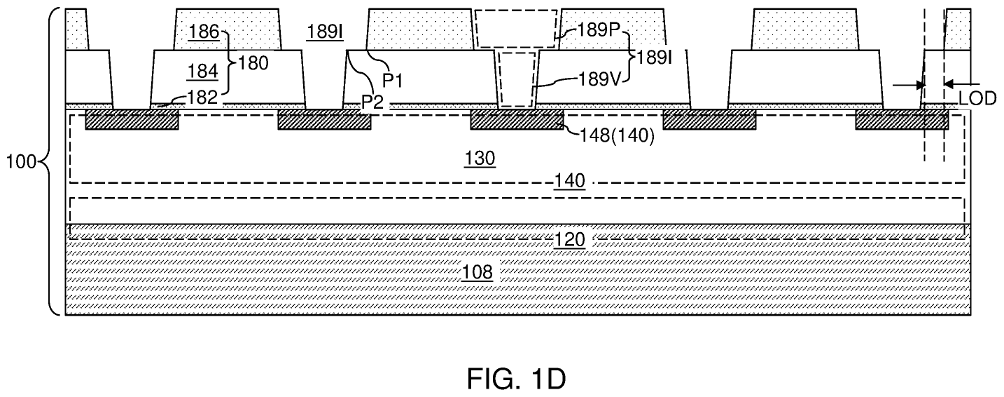

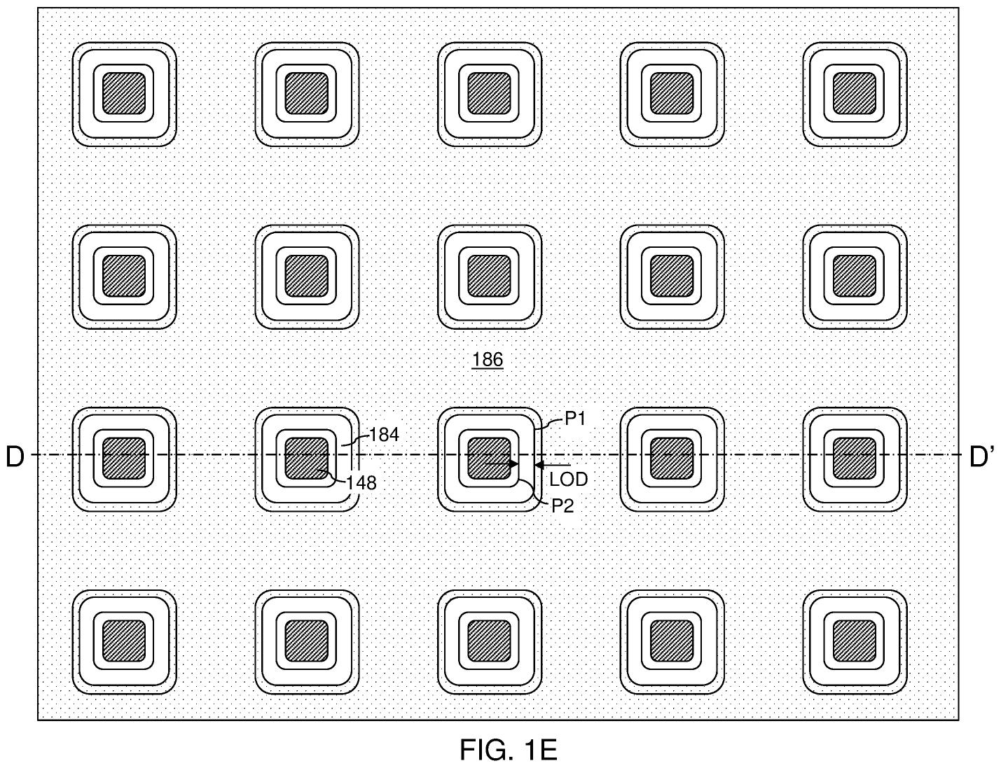

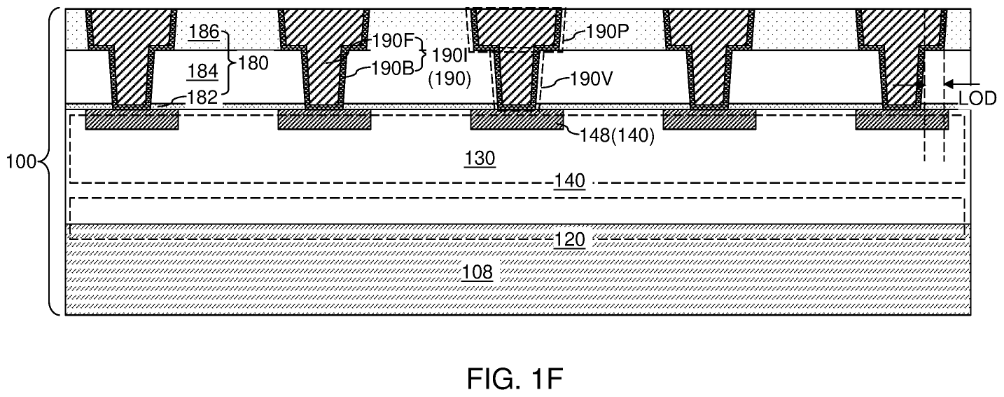

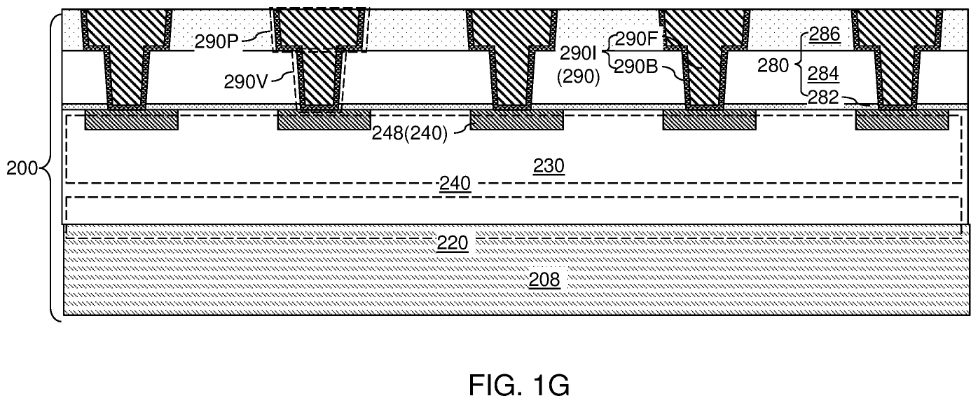

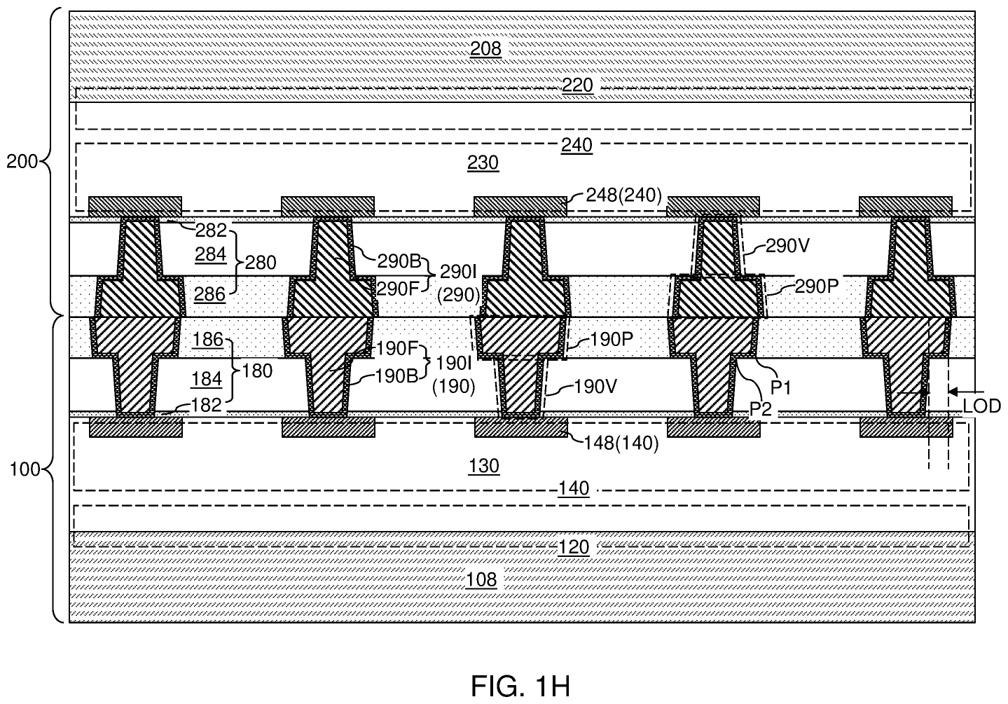

Referring to FIG. 1A, a first exemplary structure according to an embodiment of the present disclosure is illustrated. The first exemplary structure comprises a first semiconductor die 100. The first semiconductor die comprises a first substrate 108, first semiconductor devices 120 formed on, over and/or in the first substrate 108, first dielectric material layers 130 that are formed over the first semiconductor devices 120 and embedding first metal interconnect structures 140, and a first bonding-level dielectric layer 180 that is formed over the first dielectric material layers 130.

The first substrate 108 may comprise a semiconductor substrate, such as a single-crystalline silicon substrate or a semiconductor-on-insulator substrate including a single-crystalline semiconductor layer at least at an upper portion thereof. In one embodiment, the first substrate 108 may comprise a commercially available single-crystalline silicon substrate on which a two-dimensional array of memory dies are formed. In some embodiments, the first substrate 108 may be a carrier substrate which is subsequently removed (for example, by grinding, polishing, and/or by etching) from the first semiconductor devices 120 after the first semiconductor die 100 is bonded to a second semiconductor die.

The first semiconductor devices 120 may comprise any type of semiconductor devices known in the art. Generally, the first semiconductor devices 120 may comprise logic devices (such as CMOS transistors), memory devices (such as a two-dimensional memory array or a three-dimensional memory array including alternating stacks of insulating layers and electrically conductive layers and vertical stacks of memory elements and vertical semiconductor channels vertically extending through a respective one of the alternating stacks), or any other type of semiconductor device.

The first metal interconnect structures 140 may comprise metal line structures and metallic via structures. The general location of the first metal interconnect structures 140 is represented by a dotted rectangle, and that structural details of the first metal interconnect structures 140 are not illustrated in the drawings for clarity. The first metal interconnect structures 140 may have any configuration known in the art. In some embodiments, combinations of a metal line structure and at least one metallic via structure may be formed as integrated metal line-and-via structures. The first metal interconnect structures 140 can be electrically connected to the first semiconductor devices 120. The first metal interconnect structures 140 can provide electrical connection between the first semiconductor devices 120, and between the first semiconductor devices 120 and the first metallic bonding structures to be subsequently formed in the first bonding-level dielectric layer 180. First topmost metal interconnect structures 148, which are a subset of the first metal interconnect structures 140, are illustrated. In one embodiment, the first topmost metal interconnect structures 148 may have the same pattern as the pattern of a two-dimensional array of first metallic bonding structures to be subsequently formed in the first bonding-level dielectric layer 180. In one embodiment, the first topmost metal interconnect structures 148 may be arranged in a pattern of a rectangular array or in a pattern of a hexagonal array.

In one embodiment, the first bonding-level dielectric layer 180 comprises a first etch-stop dielectric layer 182, a first silicate glass layer 184, and a first dielectric bonding material layer 186. The first etch-stop dielectric layer 182 comprises a dielectric material that can be employed as an etch-stop structure. For example, the first etch-stop dielectric layer 182 may comprise silicon nitride, silicon carbide, silicon carbide nitride (i.e., silicon carbonitride) and/or a dielectric metal oxide. The thickness of the first etch-stop dielectric layer 182 may be in a range from 10 nm to 50 nm, although lesser and greater thicknesses may also be employed. The first silicate glass layer 184 comprises a silicate glass material, such as undoped silicate glass (i.e., silicon oxide) or a doped silicate glass. The thickness of the first silicate glass layer 184 may be in a range from 200 nm to 3,000 nm, such as from 500 nm to 1,000 nm, although lesser and greater thicknesses may also be employed.

The first dielectric bonding material layer 186 comprises a dielectric material that can be employed for dielectric-to-dielectric bonding with another dielectric material, and can be etched selective to the material of the first silicate glass layer 184, i.e., selective to the undoped silicate glass material or selective to the doped silicate glass material. In one embodiment, the first dielectric bonding material layer 186 may comprise and/or may consist essentially of silicon carbide nitride (i.e., silicon carbonitride). In one embodiment, the first dielectric bonding material layer 186 comprises and/or consists of a first silicon carbide nitride layer. The thickness of the first dielectric bonding material layer 186 may be in a range from 200 nm to 2,000 nm, such as from 300 nm to 600 nm, although lesser and greater thicknesses may also be employed.

Referring to FIGS. 1B and 1C, a hard mask layer 188 can be formed over the first dielectric bonding material layer 186. The hard mask layer 188 may comprise a carbon-based material, a conductive material or an insulating material, and may have a thickness in a range from 50 nm to 200 nm, although lesser and greater thicknesses may also be employed. In one embodiment, the hard mask layer 188 may comprise and/or may consist essentially of the carbon-based material including carbon at an atomic percentage greater than 80%. In an illustrative example, the hard mask layer 188 may comprise and/or may consist essentially of amorphous carbon, diamond-like carbon, or a doped carbon. Alternatively, the hard mask layer 188 may include a bilayer of a lower carbon-based material sublayer and an upper silicate glass (e.g., spin-on glass) sublayer.

The hard mask layer 188 can be patterned to form an array of openings therethrough. For example, a photoresist layer (not shown) can be applied over the hard mask layer 188, and can be lithographically patterned to form openings therein. A first anisotropic etch process can be performed to transfer the pattern of the openings in the photoresist layer through the hard mask layer 188. In one embodiment, the pattern of the openings in the hard mask layer 188 may be the same as the pattern of the first topmost metal interconnect structures 148. In one embodiment each opening in the hard mask layer 188 may be formed entirely within the area of a respective underlying first topmost metal interconnect structure 148. The photoresist layer may be removed, for example, by ashing.

A second anisotropic etch process can be performed to transfer the pattern of the openings in the hard mask layer 188 through the first bonding-level dielectric layer 180. The second anisotropic etch process can be performed employing the hard mask layer 188 as an etch mask. Via cavities 189′ are formed through the first bonding-level dielectric layer 180 such that a top surface of a respective first topmost metal interconnect structure 148 is physically exposed underneath each via cavity 189′. In one embodiment, each via cavity 189′ vertically extends through the first dielectric bonding material layer 186, the first silicate glass layer 184, and the first etch-stop dielectric layer 182. At least one of the via cavities 189′ may have a tapered sidewall to provide a variable lateral extent for a respective via cavity 189′ which increases with a vertical distance from the first substrate 108. The lateral extent (such as a diameter or a sidewall-to-sidewall distance) of each via cavity 189′ at the bottom of each via cavity 189′ may be in a range from 150 nm to 1,000 nm, such as from 300 nm to 700 nm, although lesser and greater lateral extents may also be employed.

Referring to FIGS. 1D and 1E, the hard mask layer 188 can be removed selective to the materials of the first bonding-level dielectric layer 180. In one embodiment, the hard mask layer 188 may be removed by ashing.

A selective etch process can be performed to recess the material of the first dielectric bonding material layer 186 selective to the materials of the first silicate glass layer 184, the first etch-stop dielectric layer 182, and the first topmost metal interconnect structures 148. In one embodiment, the selective etch process may comprise an isotropic etch process. In case the first dielectric bonding material layer 186 comprises silicon carbide nitride, a wet etch chemistry that may be employed to etch silicon carbide nitride selective to a silicate glass material of the first silicate glass layer 184 include, but are not limited to, wet etch chemistries employing one or more of hot phosphoric acid, potassium hydroxide, tetramethylammonium hydroxide (TMAH), and organic solvents such as n-methyl-2-pyrrolidone (NMP) or dimethyl sulfoxide (DMSO). Alternatively, a dry etch process using an NF₃/Ar plasma with an optional addition of SiCl₄ may be used to selectively etch silicon carbide nitride.

As used herein, an etch process that etches a first material is selective to a second material if the etch rate of the first material during the etch process is at least 3 times the etch rate of the second material during the etch process. As used herein, a “selectivity” of an etch process that etches a first material with respective to a second material is defined as the ratio of the etch rate of the first material to the etch rate of the second material. The selectivity of the selective etch process with respective to the material of the first silicate glass layer 184, i.e., the ratio of the etch rate of the material of the first dielectric bonding material layer 186 to the etch rate of the material of the first silicate glass layer 184 during the selective etch process may be at least 3, and/or at least 5, and/or at least 10, and/or at least 30, such as 3 to 100.

In one embodiment, the selective etch process is isotropic. In this case, the selective etch process reduces the thickness of the first dielectric bonding material layer 186 by a same dimension as a lateral etch distance of sidewalls of the first dielectric bonding material layer 186 around the via cavities 189. The selective etch process laterally expands the volumes of the via cavities 189′ at the level of the first dielectric bonding material layer 186 without expanding or with insignificant expansion of the via cavities 189′ at the level of the first silicate glass layer 184 to form a pad cavity portions 189P of first integrated pad-and-via cavities 189I. Thus, the via cavities 189′ can be converted into the first integrated pad-and-via cavities 189I by performing a selective etch process that etches the material of the first dielectric bonding material layer 186 selective to the material of the first silicate glass layer 184. Each of the first integrated pad-and-via cavities 189I comprises a respective via cavity 189V that is laterally surrounded by the first silicate glass layer 184 and further comprises a respective pad cavity 189P that is laterally surrounded by the first dielectric bonding material layer 186.

In one embodiment, at least one of the first integrated pad-and-via cavities 189I may comprise a respective first sidewall which is a sidewall of the first dielectric bonding material layer 186, a respective second sidewall which is a sidewall of the first silicate glass layer 184, and a horizontal connecting surface that connects a bottom periphery (which is herein referred to as a first periphery P1) of the first sidewall and a top periphery (which is herein referred to as a second periphery P2) of the second sidewall. In one embodiment, the selective etch process is isotropic. In this case, the first periphery P1 may be laterally offset outward from the second periphery P2 by a uniform lateral offset distance LOD, which is the same for each pair of a first periphery P1 and a second periphery P2 for any first integrated pad-and-via cavity 189I. The uniform lateral offset distance LOD may be in a range from 100 nm to 600 nm, such as from 200 nm to 500 nm, although lesser and greater lateral offset distances may also be employed.

Referring to FIG. 1F, at least one electrically conductive (e.g., metallic) material can be deposited in the integrated pad-and-via cavities 189I, and excess portions of the at least one metallic material can be removed from above the horizontal plane including the top surface of the first dielectric bonding material layer 186 by performing a planarization process. In one embodiment, the at least one metallic material may comprise a combination of a conductive metallic barrier material and a metallic fill material. The conductive metallic barrier material may comprise a metallic nitride or carbide material, such as WN, TiN, TaN, MON, TiC, TaC, and/or WC, and may have thickness in a range from 5 nm to 50 nm, although lesser and greater thicknesses may also be employed. The conductive metallic barrier material may be deposited by physical vapor deposition or by chemical vapor deposition. The metallic fill material comprises a high-conductivity metal, such as W, Cu, Al, Mo, Co, Ru, alloys thereof, such as Cu—Al, etc. The metallic fill material may be deposited by physical vapor deposition, electroplating, electroless plating, and/or chemical vapor deposition. The planarization process that may be employed to remove excess portions of the at least one metallic material from above the horizontal plane including the top surface of the first dielectric bonding material layer 186 may employ chemical mechanical polishing.

Each remaining portion of the at least one metallic material that fills a respective first integrated pad-and-via cavity 189I constitutes a first integrated pad-and-via bonding structure 190I, which is a type of a first metallic bonding structure 190. In one embodiment, each of the first integrated pad-and-via bonding structures 190I comprises a combination of a first metallic barrier liner 190B (which is a patterned portion of the conductive metallic barrier material) and a first metallic fill material portion 190F (which is a patterned portion of the metallic fill material). In one embodiment, each of the first integrated pad-and-via bonding structures 190I comprises a respective metallic via portion 190V that is laterally surrounded by the first silicate glass layer 184 and a respective metallic pad portion 190P that is laterally surrounded by the first dielectric bonding material layer 186. In one embodiment, bottom surfaces of the metallic pad portions 190P of the first integrated pad-and-via bonding structures 190I may be formed within a horizontal plane including an interface between the first silicate glass layer 184 and the first dielectric bonding material layer 186 (which may be a first silicon carbide nitride layer).

In one embodiment, at least one of the first integrated pad-and-via bonding structures 190I may comprise a respective first metallic barrier liner 190B that contacts a sidewall of the first silicate glass layer 184, a horizontal surface of the first silicate glass layer 184, and a sidewall of the first dielectric bonding material layer 186 (which may be a first silicon carbide nitride layer). In one embodiment, the first bonding-level dielectric layer 180 also comprises a first etch-stop dielectric layer 182 that underlies the first silicate glass layer 184, and contacting and laterally surrounding the first metallic barrier liner 190B.

Referring to FIG. 1G, a second semiconductor die 200 may be provided. The second semiconductor die comprises a second substrate 208, second semiconductor devices 220 formed above, on and/or in the second substrate 208, second dielectric material layers 230 that are formed over the second semiconductor devices 220 and embedding second metal interconnect structures 240, and a second bonding-level dielectric layer 280 that is formed over the second dielectric material layers 230. The second substrate 208 may comprise any substrate that may be employed for the first substrate 108. The second semiconductor devices 220 may comprise any type of semiconductor devices known in the art. In one embodiment, the first semiconductor devices 220 may comprise a memory array and the second semiconductor devices 220 may comprise a peripheral (i.e., driver) circuit configured to control operation of the memory array, or vice versa. The second metal interconnect structures 240 may be electrically connected to the second semiconductor devices 220.

Second topmost metal interconnect structures 248, which are a subset of the second metal interconnect structures 240, are also illustrated in FIG. 1G. In one embodiment, the second topmost metal interconnect structures 248 may have the same pattern as the pattern of a two-dimensional array of second metallic bonding structures to be subsequently formed in the second bonding-level dielectric layer 280. In one embodiment, the second topmost metal interconnect structures 248 may be arranged in a pattern of a rectangular array or in a pattern of a hexagonal array. In one embodiment, the pattern of the second topmost metal interconnect structures 248 may be a mirror image pattern of the pattern of the first integrated pad-and-via bonding structures 190I.

The second bonding-level dielectric layer 280 comprises a second etch-stop dielectric layer 282, a second silicate glass layer 284, and a second dielectric bonding material layer 286. The second etch-stop dielectric layer 282 comprises a dielectric material that can be employed as an etch-stop structure. For example, the second etch-stop dielectric layer 282 may comprise silicon nitride, silicon carbide, silicon carbide nitride, and/or a dielectric metal oxide. The thickness of the second etch-stop dielectric layer 282 may be in a range from 10 nm to 50 nm, although lesser and greater thicknesses may also be employed. The second silicate glass layer 284 comprises a silicate glass material such as undoped silicate glass or a doped silicate glass. The thickness of the second silicate glass layer 284 may be the same as that of the first silicate glass layer 184. The second dielectric bonding material layer 286 may comprise the same material (e.g., silicon carbide nitride) and the same thickness as the first dielectric bonding material layer 186.

The processing steps described with reference to FIGS. 1B-1E may be performed with any needed changes on the second semiconductor die 200 to form second integrated pad-and-via bonding structures 290I through the second bonding-level dielectric layer 280. The second integrated pad-and-via bonding structures 290I are second metallic bonding structures 290. In one embodiment, each of the second integrated pad-and-via bonding structures 290I comprises a combination of a second metallic barrier liner 290B (which is a patterned portion of a conductive metallic barrier material) and a second metallic fill material portion 290F (which is a patterned portion of a metallic fill material). In one embodiment, each of the second integrated pad-and-via bonding structures 290I comprises a respective metallic via portion 290V that is laterally surrounded by the second silicate glass layer 284 and a respective metallic pad portion 290P that is laterally surrounded by the second dielectric bonding material layer 286. In one embodiment, bottom surfaces of the metallic pad portions 290P of the second integrated pad-and-via bonding structures 290I may be formed within a horizontal plane including an interface between the second silicate glass layer 284 and the second dielectric bonding material layer 286 (which may be a second silicon carbide nitride layer).

In one embodiment, at least one of the second integrated pad-and-via bonding structures 290I, may comprise a respective second metallic barrier liner 290B that contacts a sidewall of the second silicate glass layer 284, a horizontal surface of the second silicate glass layer 284, and a sidewall of the second dielectric bonding material layer 286 (which may be a second silicon carbide nitride layer). In one embodiment, the second bonding-level dielectric layer 280 also comprises a second etch-stop dielectric layer 282 that underlies the second silicate glass layer 284 and contacting and laterally surrounding the second metallic barrier liner 290B.

In summary, a second semiconductor die 200 can be provided, which includes second dielectric material layers 230 located on second semiconductor devices 220 and embedding second metal interconnect structures 240, and further includes a second bonding-level dielectric layer 280 embedding metallic bonding structures, such as the second metallic bonding structures 290.

Referring to FIG. 1H, the second metallic bonding structures 290 (which may comprise second integrated pad-and-via bonding structures 290I) can be bonded to the first metallic bonding structures 190 (which may comprise first integrated pad-and-via bonding structures 190I) by metal-to-metal bonding. As used herein, “metal-to-metal” bonding refers to a direct bonding between mating pairs of bonding pads. Thus, there is no intervening metallic material such as a solder material between mating pairs of bonding pads that are bonded to each other via metal-to-metal bonding. In one embodiment, the second metallic bonding structures 290 (which may comprise second integrated pad-and-via bonding structures 290I) can be bonded to the first integrated pad-and-via bonding structures 190I by copper-to-copper bonding, which is a metal-to-metal bonding between at least one pair of copper pads. In this case, the first metallic fill material portions 190F and the second metallic fill material portion 290F may consist essentially of copper or copper alloy.

In one embodiment, a dielectric-to-dielectric bonding may also be performed between the second bonding-level dielectric layer 280 and the first dielectric bonding material layer 186 in addition to the metal-to-metal bonding. Generally, each of the second dielectric bonding material layer 286 and the first dielectric bonding material layer 186 comprises and/or consists essentially of a respective dielectric material that may be employed for dielectric-to-dielectric bonding. In one embodiment, the first and the second dielectric bonding material layers (186. 286) comprise and/or consist essentially of silicon carbide nitride.

In one embodiment, at least one of the first integrated pad-and-via bonding structures 190I may comprise a respective first sidewall which contacts a sidewall of the first dielectric bonding material layer 186, a respective second sidewall which contacts a sidewall of the first silicate glass layer 184, and a horizontal connecting surface that connects a bottom periphery (which is herein referred to as a first periphery P1) of the first sidewall and a top periphery (which is herein referred to as a second periphery P2) of the second sidewall. According to an aspect of the present disclosure, for any first integrated pad-and-via bonding structure 190I, the first periphery P1 may be laterally offset outward from the second periphery P2 by a uniform lateral offset distance LOD. In one embodiment, the first pad-and-via bonding structures 190I include a wider metallic pad portion 190P and a narrower metallic via portion 190V. The wider metallic pad portion 190P may have a critical diameter at its top surface of greater than 400 nm, such as 500 to 1,000 nm for improved overlay with the second pad-and-via bonding structures 290I. In contrast, the narrower metallic via portion 190V may have a critical diameter at its bottom surface of 200 nm or less, such as 140 to 200 nm for improved overlay and contact to the relatively narrow underlying first topmost metal interconnect structure 148, which may have a critical diameter at its top surface of less than 300 nm, such as 200 to 250 nm. In one embodiment, the entire bottom surface of the narrower metallic via portion 190V may contact the top surface of the underlying first topmost metal interconnect structure 148 without any portion of the bottom surface of the narrower metallic via portion 190V located outside of the periphery of the top surface of the underlying first topmost metal interconnect structure 148 (i.e., there is complete overlay between the bottom of the portion 190V and the top of the structure 148).

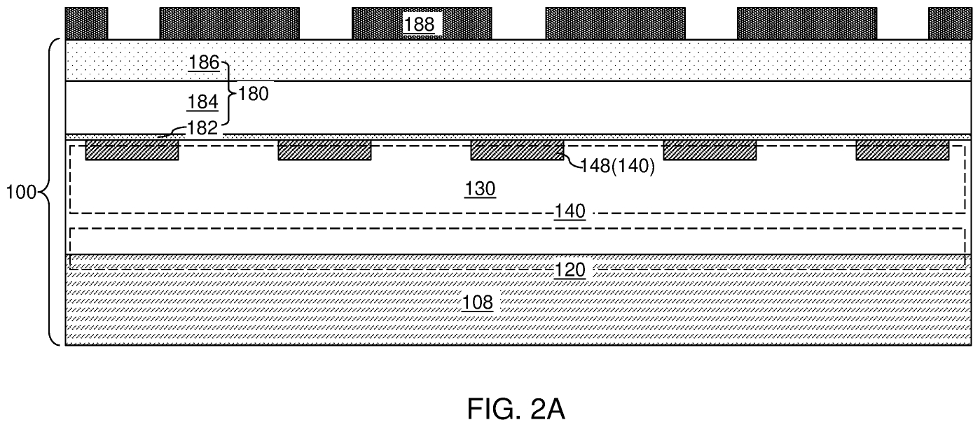

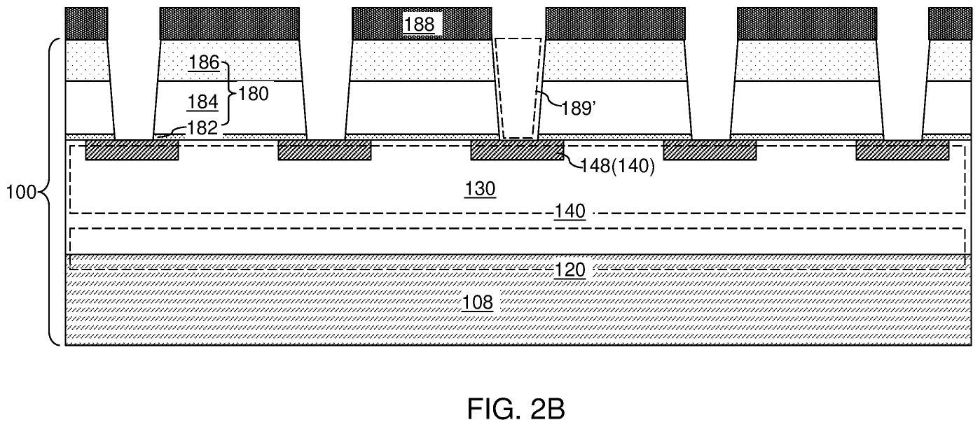

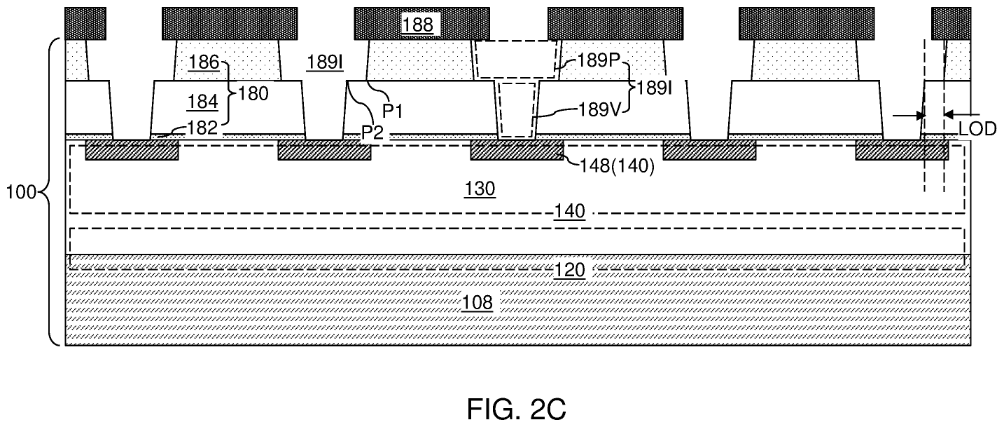

FIGS. 2A-2C are sequential vertical cross-sectional views of a second exemplary structure during formation of the first semiconductor die 100 according to an embodiment of the present disclosure.

Referring to FIG. 2A, the second exemplary structure can be derived from the first exemplary structure illustrated in FIGS. 1B and 1C by selecting the thickness of the first dielectric bonding material layer 186 to be the same as the final thickness of the first dielectric bonding material layer 186 after the processing steps of FIGS. 1D and 1E. For example, the thickness of the first dielectric bonding material layer 186 may be in a range from 200 nm to 1,000 nm, such as from 300 nm to 600 nm, although lesser and greater thicknesses may also be employed. The hard mask layer 188 may be the same as described with reference to FIGS. 1B and 1C.

Referring to FIG. 2B, the second anisotropic etch process described with reference to FIGS. 1B and 1C can be performed to form via cavities 189′.

Referring to FIG. 2C, the selective etch process described with reference to FIGS. 1D and 1E can be performed to convert the via cavities 189′ into first integrated pad-and-via cavities 189I while the hard mask layer 188 is present on the top surface of the first dielectric bonding material layer 186. Each first integrated pad-and-via cavity 189I may comprise a respective via cavity 189V that is laterally surrounded by the first silicate glass layer 184 and further comprises a respective pad cavity 189P that is laterally surrounded by the first dielectric bonding material layer 186. In this case, the thickness of the first dielectric bonding material layer 186 remains unchanged during the selective etch process.

Subsequently, the hard mask layer 188 can be removed selective to the first dielectric bonding material layer 186, the first silicate glass layer 184, the first etch-stop dielectric layer 182, and the first topmost metal interconnect structures 148, for example, by ashing. In one embodiment, at least one of the first integrated pad-and-via cavities 189I may comprise a respective first sidewall which is a sidewall of the first dielectric bonding material layer 186, a respective second sidewall which is a sidewall of the first silicate glass layer 184, and a horizontal connecting surface that connects a bottom periphery (which is herein referred to as a first periphery P1) of the first sidewall and a top periphery (which is herein referred to as a second periphery P2) of the second sidewall. According to an aspect of the present disclosure, the selective etch process is isotropic. Thus, the first periphery P1 may be laterally offset outward from the second periphery P2 by a uniform lateral offset distance LOD, which is the same for each pair of a first periphery P1 and a second periphery P2 for any first integrated pad-and-via cavity 189I. The uniform lateral offset distance LOD may be in a range from 200 nm to 600 nm, such as from 300 nm to 500 nm, although lesser and greater lateral offset distances may also be employed.

The processing steps described with respect to FIGS. 1F, 1G, and 1H can be subsequently performed to form the first semiconductor die 100 including first integrated pad-and-via bonding structures 190I, to form the second semiconductor die 200, and to form a bonded assembly of the first semiconductor die 100 and the second semiconductor die 200. A bonded assembly derived from the second exemplary structure illustrated in FIG. 2C may be the same as the bonded assembly illustrated in FIG. 1H.

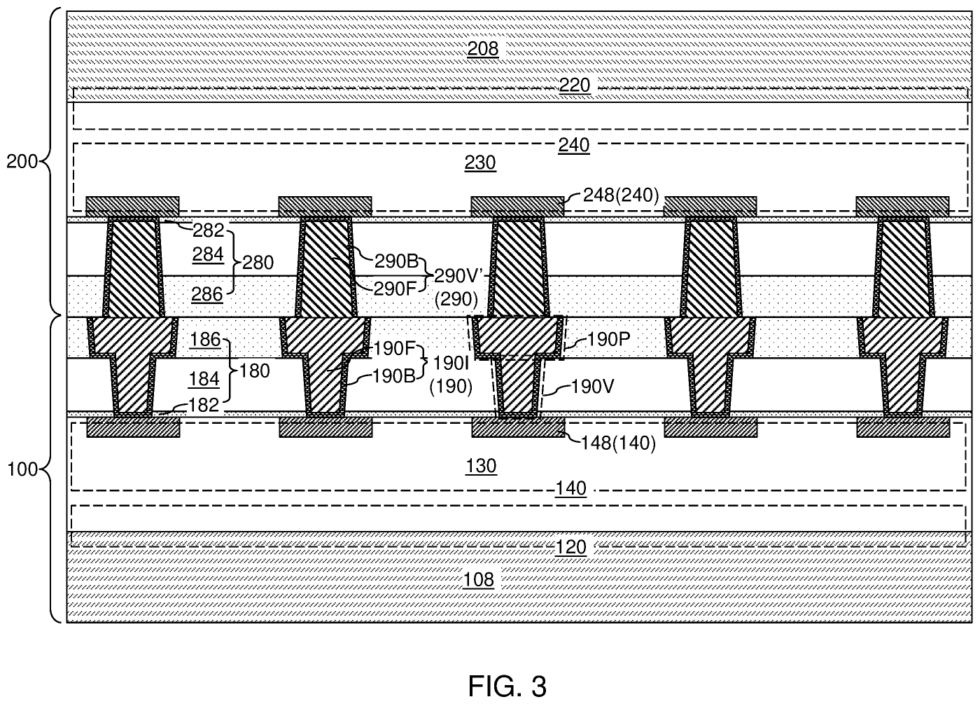

Referring to FIG. 3, a third exemplary structure can be derived from the first exemplary structure illustrated in FIG. 1H by employing via bonding structures 290V′ as second metallic bonding structures 290. In this case, the via bonding structures 290V′ may be formed by forming a two-dimensional array of via cavities through the second bonding-level dielectric layer 280, by filling the two-dimensional array of via cavities with at least one metallic material, and by removing portions of the at least one metallic material that are located outside the volumes of the two-dimensional array of via cavities. Each of the via bonding structures 290V′ may consist of a respective metallic via portion, which may comprise a combination of a second metallic barrier liner 290B (which is a patterned portion of a conductive metallic barrier material) and a second metallic fill material portion 290F (which is a patterned portion of a metallic fill material). A two-dimensional array of first integrated pad-and-via bonding structures 190I of the first semiconductor die 100 can be bonded to a two-dimensional array of via bonding structures 290V′ (which is a two-dimensional array of second metallic bonding structures) through metal-to-metal bonding.

In this embodiment, the second metallic bonding structures 290 comprise via bonding structures 290V′ which exclude the pad portion 290P of the previous embodiment. In one embodiment, each of the via bonding structures 290V′ comprises a respective straight sidewall that extends through an entirety of the second silicate glass layer 284 and through an entirety of the second dielectric bonding material layer 286. In one embodiment, the sidewall of at least one of the straight sidewalls of the via bonding structures 290V′ may vertically extend from a bonding interface between the first semiconductor die 100 and the second semiconductor die 200 to a surface of a respective second topmost metal interconnect structure 248.

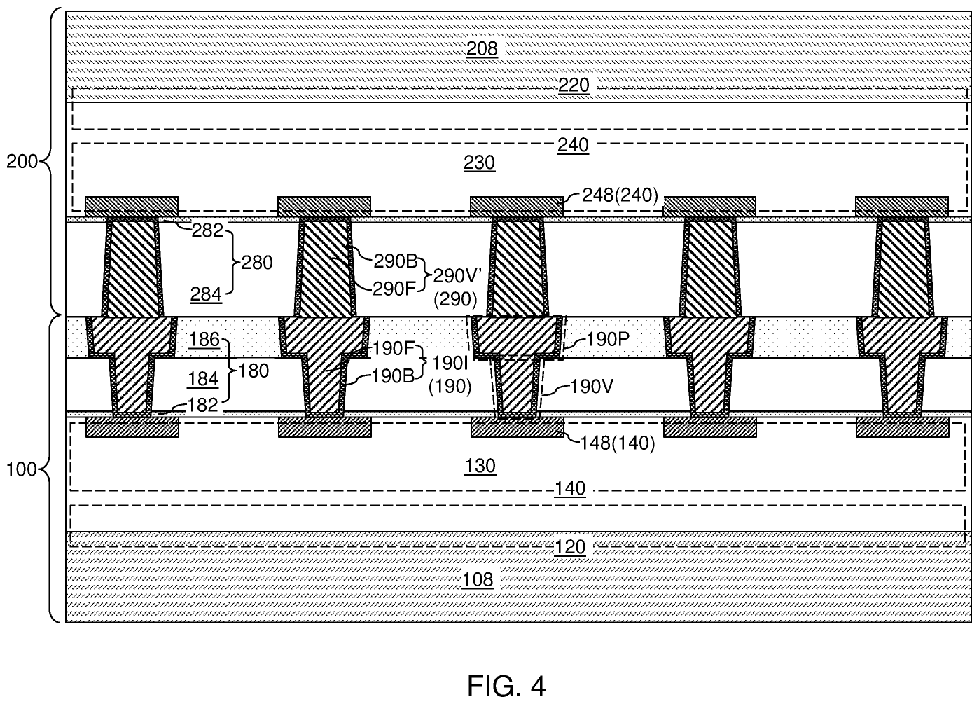

Referring to FIG. 4, a fourth exemplary structure can be derived from the third exemplary structure by replacing the combination of a second silicate glass layer 284 and a second dielectric bonding material layer 286 with a second silicate glass layer 284. The thickness of the second silicate glass layer 284 in the fourth exemplary structure may be the same as the sum of the thickness of the second silicate glass layer 284 and the thickness of the second dielectric bonding material layer 286 in the third exemplary structure illustrated in FIG. 3.

In this embodiment, the second bonding-level dielectric layer 280 comprises a layer stack including a second silicate glass layer 284 and an etch-stop dielectric layer (such as a second etch-stop dielectric layer 282). In one embodiment, the second metallic bonding structures 290 comprise via bonding structures 290V′. Each via bonding structure 290V′ comprises a respective straight sidewall that extends through an entirety of the second silicate glass layer 284 and through an entirety of the etch-stop dielectric layer.

Referring collectively to FIGS. 1A-1H, 2A-2C, 3, and 4, a bonded assembly of a first semiconductor die 100 and a second semiconductor die 200 is illustrated. The first semiconductor die 100 comprises: first dielectric material layers 130 located on first semiconductor devices 120; first metal interconnect structures 140 embedded in the first dielectric material layers 130 and electrically connected to the first semiconductor devices 120; a first bonding-level dielectric layer 180 located on the first dielectric material layers 130 and comprising a layer stack including a first silicate glass layer 184 and a first silicon carbide nitride layer (which is embodied as a first dielectric bonding material layer 186); and first integrated pad-and-via bonding structures 190I comprising a respective metallic via portion 190V that is laterally surrounded by the first silicate glass layer 184 and a respective metallic pad portion 190P that is laterally surrounded by the first silicon carbide nitride layer and bonded to a respective second metallic bonding structure 290 of the second semiconductor die 200 through metal-to-metal bonding. At least one of the first integrated pad-and-via bonding structures 190I comprises a first metallic barrier liner 190B that contacts a sidewall of the first silicate glass layer 184, a horizontal surface of the first silicate glass layer 184, and an entire sidewall of the first silicon carbide nitride layer 186. The first metallic barrier liner 190B comprises an electrically conductive metal nitride or an electrically conductive metal carbide layer which extends from a bottom surface to a top surface of the first silicon carbide nitride layer 186, and which surrounds a metal or metal alloy fill material portion 190F.

In one embodiment, the second semiconductor die 200 comprises a second bonding-level dielectric layer 280 that embed the second metallic bonding structures 290 and bonded to the first silicon carbide nitride layer by dielectric-to-dielectric bonding. In one embodiment, the second bonding-level dielectric layer 280 comprises a second dielectric bonding material layer 286 that is bonded to the first silicon carbide nitride layer by the dielectric-to-dielectric bonding. In one embodiment, the second bonding-level dielectric layer 280 comprises a second silicate glass layer 284 that is bonded to the first silicon carbide nitride layer by the dielectric-to-dielectric bonding.

In one embodiment, bottom surfaces of the metallic pad portions 190P of the first integrated pad-and-via bonding structures 190I are located within a horizontal plane including an interface between the first silicate glass layer 184 and the first silicon carbide nitride layer. In one embodiment, one of the first integrated pad-and-via bonding structures 190I comprises a first metallic barrier liner 190B that contacts a sidewall of the first silicate glass layer 184, a horizontal surface of the first silicate glass layer 184, and a sidewall of the first silicon carbide nitride layer. In one embodiment, the first bonding-level dielectric layer 180 comprises a first etch-stop dielectric layer 182 that underlies the first silicate glass layer 184 and contacting, and laterally surrounding, the first metallic barrier liner 190B.

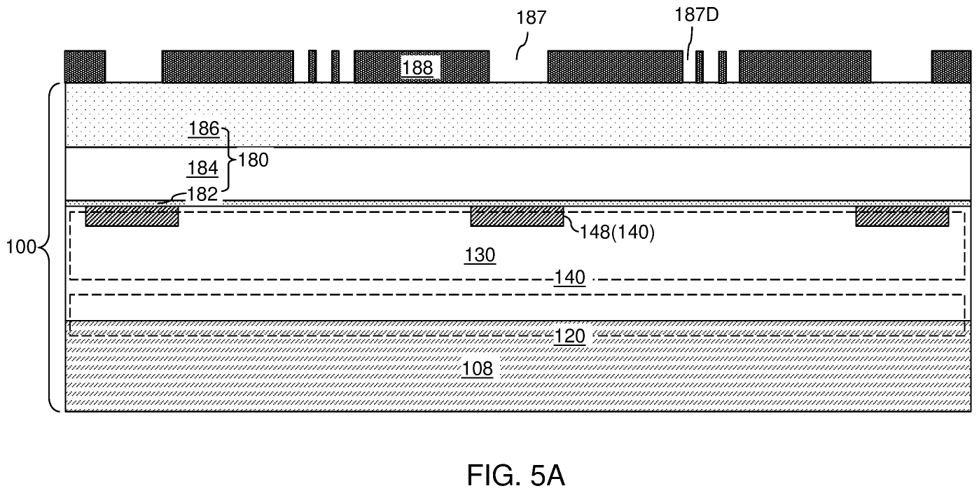

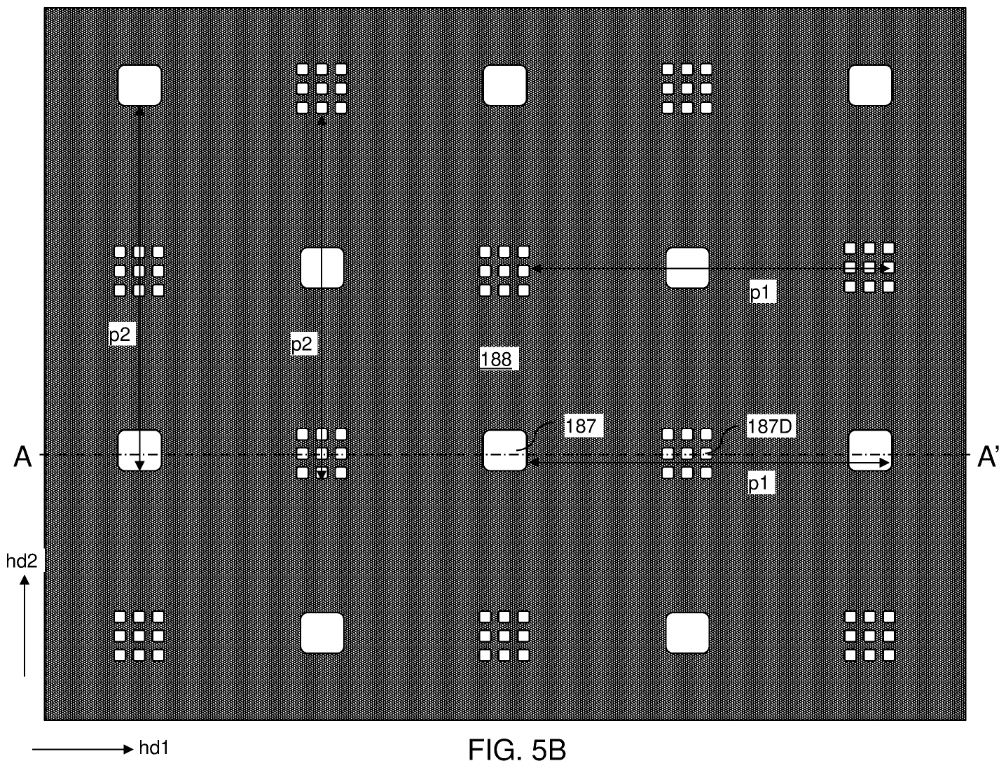

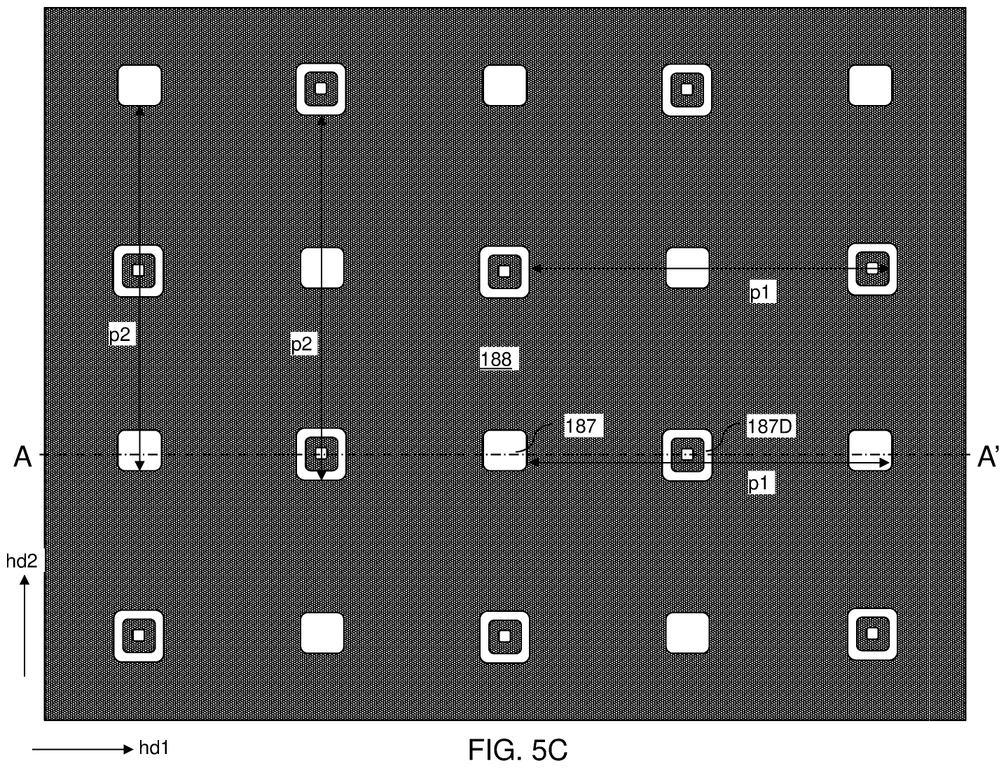

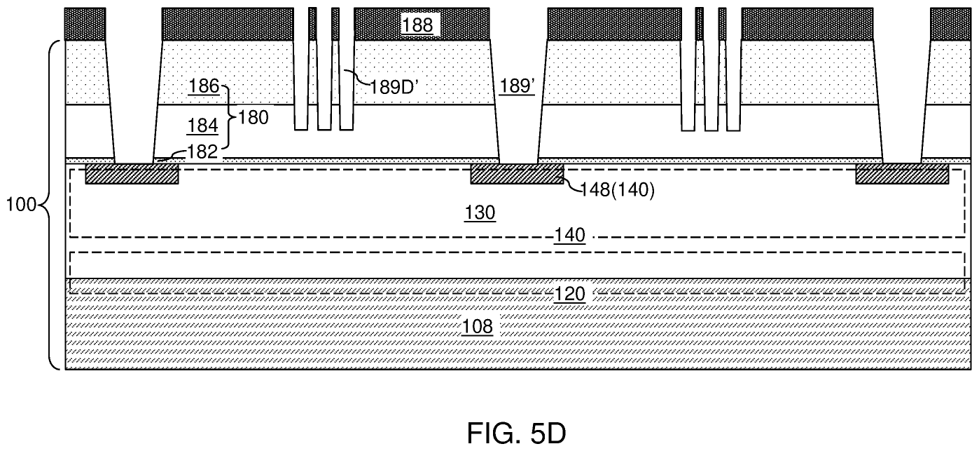

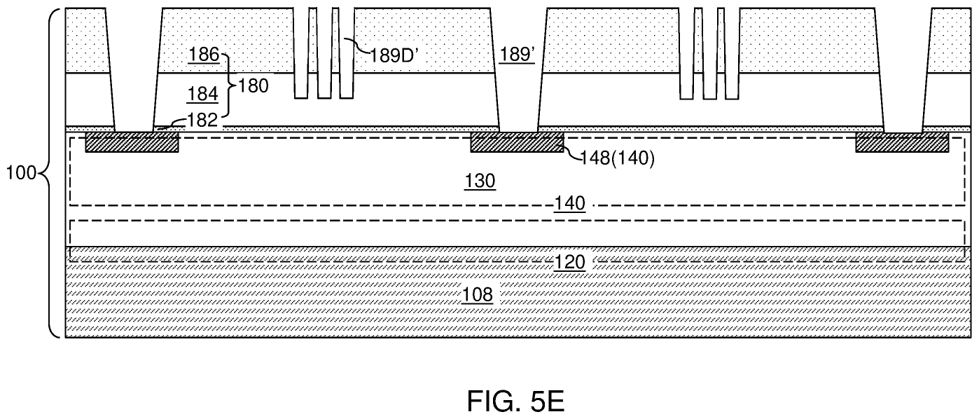

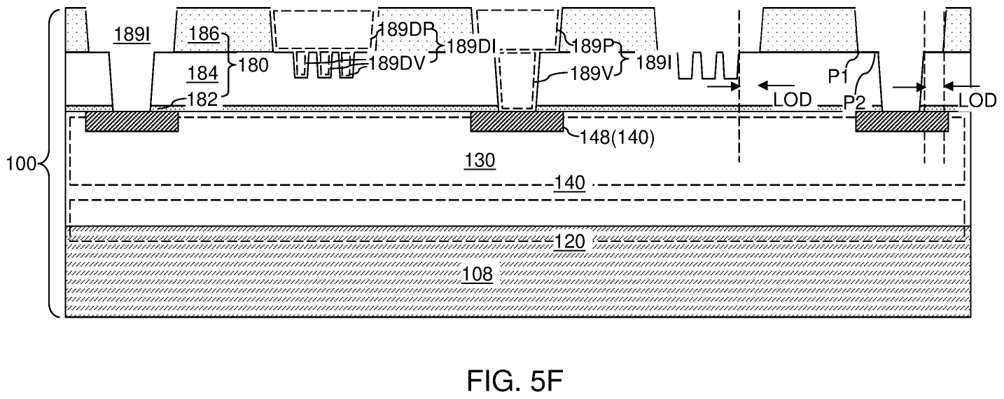

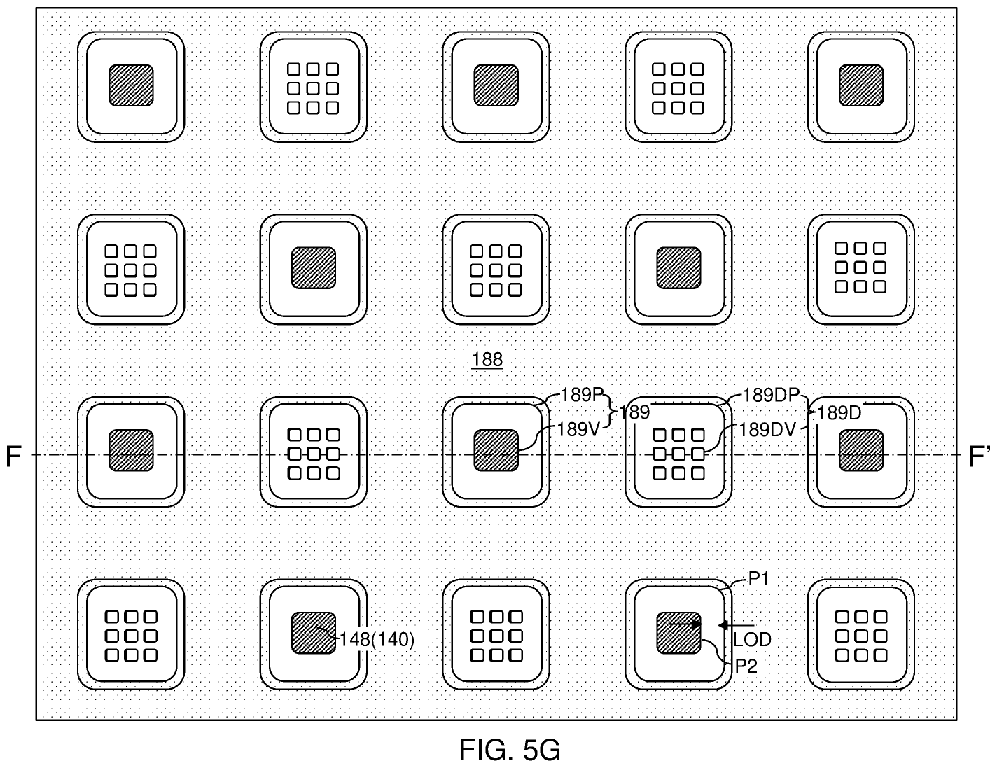

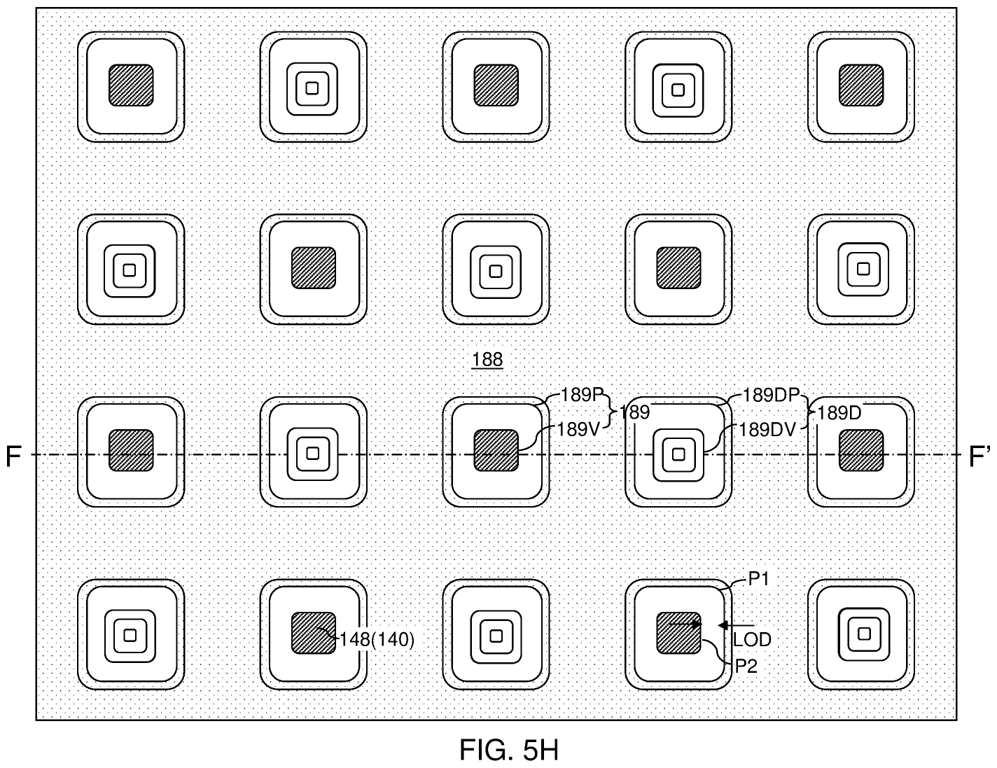

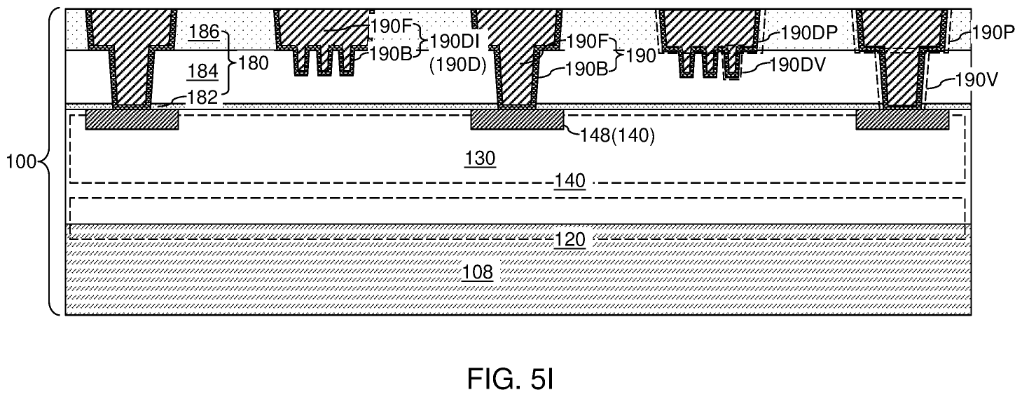

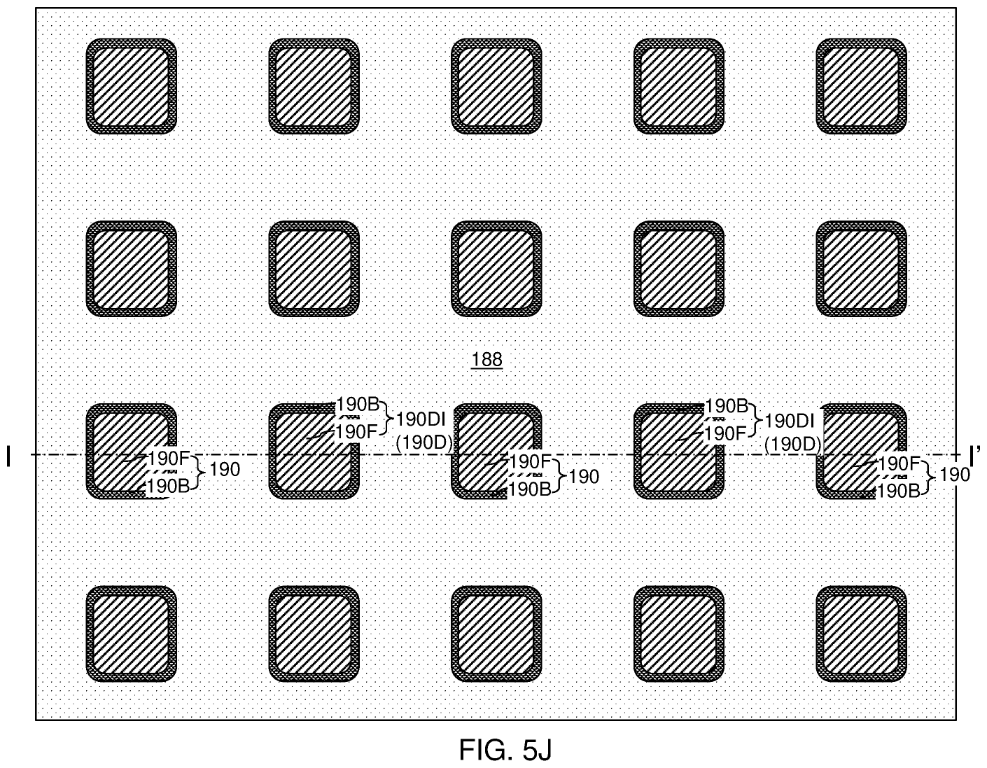

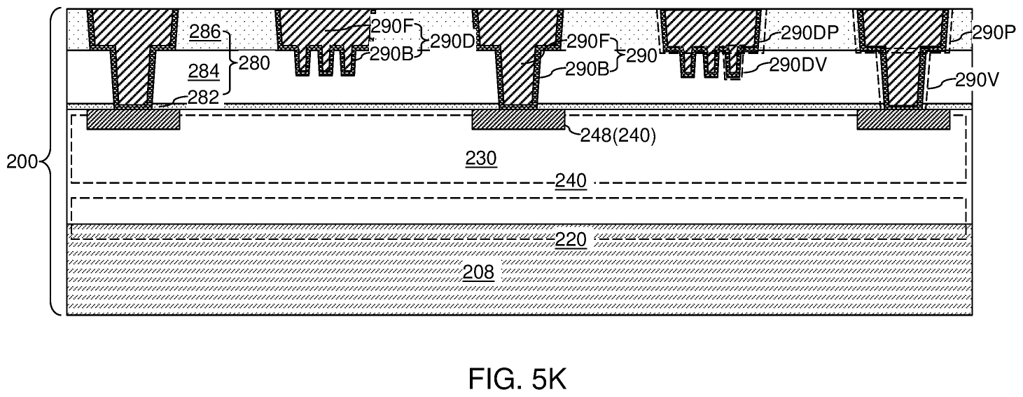

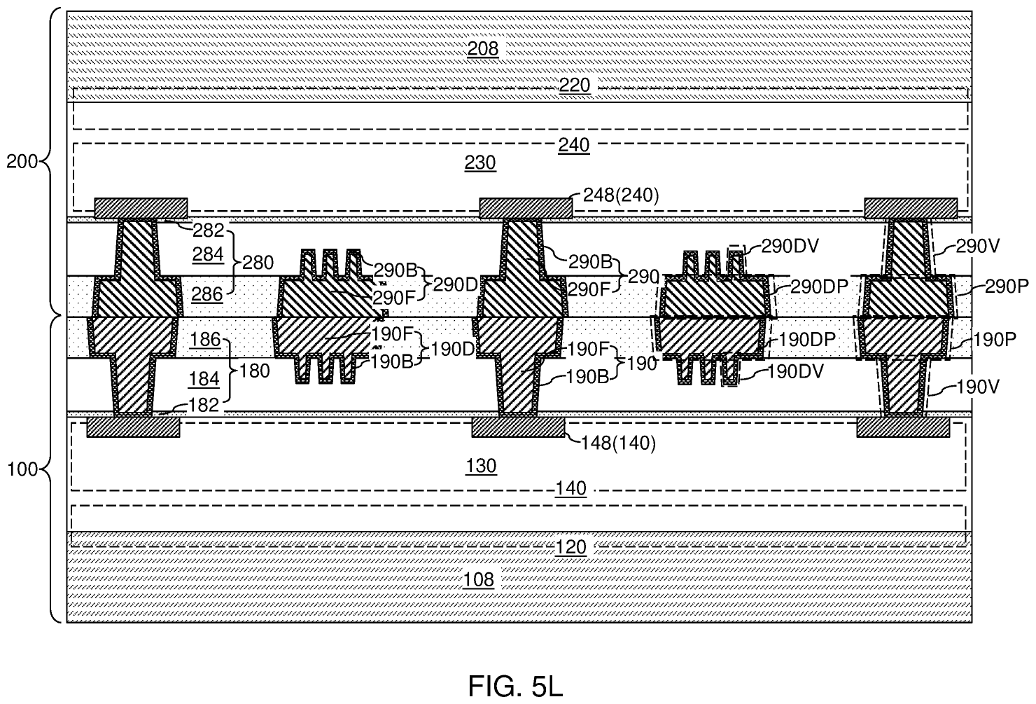

Referring to FIGS. 5A, 5B, and 5C, a fifth exemplary structure according to an embodiment of the present disclosure can be derived from the first exemplary structure illustrated in FIG. 1A by forming a hard mask layer 188 on a top surface of the first bonding-level dielectric layer 180, and by patterning the hard mask layer 188 with a composite pattern that includes a pattern of via openings 187 and a pattern of dummy via openings 187D. FIG. 5A is a vertical cross-sectional view. FIG. 5B is a top-down view of a first configuration of the fifth exemplary structure of FIG. 5A. FIG. 5C is a top-down view of a second configuration of the fifth exemplary structure of FIG. 5A. The via openings 187 can be formed as a first two-dimensional periodic array, and the dummy via openings 187D can be formed as a second two-dimensional periodic array that is interlaced with the first two-dimensional periodic array. The via openings 187 are wider than the dummy openings 187D.

In one embodiment, each unit of repetition in the first periodic array may consist of a single via opening 187 having a first width, which may be a maximum lateral dimension of the single via opening 187. The first width of a via opening 187 may be in a range from 200 nm to 1,000 nm, such as from 300 nm to 600 nm, although lesser and greater dimensions may also be employed. In one embodiment, each unit of repetition in the first periodic array may have a shape of a circle, a rectangle, a rounded rectangle, or any two-dimensional shape having a single closed periphery. In one embodiment, each unit of repetition in the second periodic array may comprise one or more dummy via openings 187D each having a respective width that is less than one half of the first width, such as one tenth to one third of the first width. In one embodiment, each unit of repetition in the second periodic array may comprise a one-dimensional array of dummy via openings 187D or a two-dimensional array of dummy via openings 187D as illustrated in FIG. 5B. In another embodiment, each unit of repetition in the second periodic array may comprise a plurality of openings that are nested in one another. For example, each unit of repetition may comprise a center opening and at least one generally ring-shaped (e.g., circular, oval or rectangular) opening that laterally surrounds the center opening as illustrated in FIG. 5C. Each dummy via opening 187D within a unit of repetition in the second periodic array may have a respective width that is less than one half of the first width of a via opening 187 in a unit of repetition in the first periodic array.

In one embodiment, the first two-dimensional periodic array of via openings 187 may have a first pitch p1 along a first horizontal direction hd1, and may have a second pitch p2 along a second horizontal direction hd2. The second two-dimensional periodic array of dummy openings 187D may have the first pitch p1 along the first horizontal direction hd1, and may have the second pitch p2 along the second horizontal direction hd2. The second two-dimensional periodic array may be laterally offset from the first two-dimensional periodic array along the first horizontal direction hd1 by one half of the first pitch p1 along the first horizontal direction hd1, and/or may be laterally offset from the first two-dimensional periodic array along the second horizontal direction hd2 by one half of the second pitch p2 along the second horizontal direction hd2. Generally, the first two-dimensional periodic array of the via openings 187 may be interlaced with the second two-dimensional periodic array of the dummy via openings 187D along the first horizontal direction hd1 and/or along the second horizontal direction hd2. The first horizontal direction hd1 and the second horizontal direction hd2 may, or may not, be perpendicular to each other.

Referring to FIG. 5D, an anisotropic etch process can be performed to etch unmasked portions of the first dielectric bonding material layer 186, the first silicate glass layer 184, and the first etch-stop dielectric layer 182. The anisotropic etch process may employ the hard mask layer 188 as an etch mask. According to an aspect of the present disclosure, the etch rate of the anisotropic etch process may be geometry-dependent, and specifically, may be aspect-ratio-dependent. As used herein, an aspect ratio refers to the ratio of a height of a cavity to a width of the cavity. The chemistry of an anisotropic etch process may be aspect-ratio-dependent if the anisotropic etch process is depletive (i.e., does not provide the etchant gas at a sufficient quantity) and/or if the anisotropic etch process generates a passivating polymer material as a byproduct of the anisotropic etch process. In this case, cavities having a low aspect ratio can be etched to a greater etch depth relative to cavities having a high aspect ratio.

Via cavities 189′ are formed underneath the first via openings 187 in the hard mask layer 188, and dummy via cavities 189D′ are formed underneath the first dummy via openings 187D in the hard mask layer 188. The duration and the etch chemistry of the anisotropic etch process can be selected such that the materials of the first dielectric bonding material layer 186, the first silicate glass layer 184, and the first etch-stop dielectric layer 182 are sequentially etched underneath the first via openings 187, and each via cavity 189′ vertically extends from a topmost surface of the first bonding-level dielectric layer 180 to the bottommost surface of the first bonding-level dielectric layer 180. Thus, a top surface of a first topmost metal interconnect structure 148 can be physically exposed underneath each via cavity 189′.

The etch rate of the materials of the first dielectric bonding material layer 186 and the first silicate glass layer 184 underneath the first dummy via openings 187D is less than the etch rate of the first dielectric bonding material layer 186 and the first silicate glass layer 184 underneath the first via openings 187. Thus, the dummy via cavities 189D′ that are formed underneath the first dummy via openings 187D have a depth that is less than the depth of the via cavities 189′, i.e., have a depth that is less than the total thickness of the first bonding-level dielectric layer 180. In one embodiment, the height of each dummy via cavity 189D′ may be in a range from 20% to 80%, such as from 30% to 70%, of the thickness of the first bonding-level dielectric layer 180. Thus, the first topmost metal interconnect structure 148 are not exposed to the dummy via cavities 189′. Generally, the via cavities 189′ vertically extend from a topmost surface of the first bonding-level dielectric layer 180 to a bottommost surface of the first bonding-level dielectric layer 180, and the dummy via cavities 189D′ have a lesser vertical extent than the via cavities 189′.

Referring to FIG. 5E, the hard mask layer 188 can be removed selective to the materials of the first dielectric bonding material layer 186, the first silicate glass layer 184, and the first etch-stop dielectric layer 182. If the hard mask layer 188 comprises a carbon-based material, the hard mask layer 188 can be removed by ashing.

Referring to FIGS. 5F, 5G, and 5H, a selective etch process can be performed to recess the material of the first dielectric bonding material layer 186 selective to the materials of the first silicate glass layer 184, the first etch-stop dielectric layer 182, and the first topmost metal interconnect structures 148. FIG. 5F is a vertical cross-sectional view. FIG. 5G is a top-down view of a first configuration of the fifth exemplary structure of FIG. 5F. FIG. 5H is a top-down view of a second configuration of the fifth exemplary structure of FIG. 5F.

In one embodiment, the selective etch process may be the same as described above with respect to FIG. 1D or FIG. 2C. The via cavities 189′ can be converted into first integrated pad-and-via cavities 189I by performing a selective etch process that etches the material of the first dielectric bonding material layer 186 selective to the material of the first silicate glass layer 184. Each of the first integrated pad-and-via cavities 189I comprises a respective via cavity 189V that is laterally surrounded by the first silicate glass layer 184 and further comprises a respective pad cavity 189P that is laterally surrounded by the first dielectric bonding material layer 186.

The selective etch process expands the volumes of the dummy via cavities 189D′ at the level of the first dielectric bonding material layer 186 without expanding or with insignificant expansion of the dummy via cavities 189D′ at the level of the first silicate glass layer 184. A plurality of dummy via cavities 189D′ within each repetition unit of the second two-dimensional periodic array can be merged at the level of the first dielectric bonding material layer 186, and can be converted into a first dummy integrated pad-and-via cavity 189DI. Each of the first dummy integrated pad-and-via cavities 189DI comprises a respective plurality of dummy via cavities 189DV that are laterally surrounded by the first silicate glass layer 184 and further comprises a respective dummy pad cavity 189DP that is laterally surrounded by the first dielectric bonding material layer 186. Thus, a plurality of dummy via cavities 189DV are located below each dummy pad cavity 189DP.

In one embodiment, a dummy pad cavity 189DP may comprise a respective first dummy-cavity sidewall which is a sidewall of the first dielectric bonding material layer 186. A set of underlying dummy via cavities 189DV may comprise second dummy-cavity sidewalls which are sidewalls of the first silicate glass layer 184. A bottom periphery of the first via-cavity sidewall can be laterally offset from proximal segments of top peripheries of the second dummy-cavity sidewalls by the uniform lateral offset distance LOD. Segments of top peripheries of neighboring pairs of dummy via cavities 189DV within each unit area of repetition may be laterally spaced from each other by a respective lateral spacing that is less than twice the lateral offset distance. Thus, each dummy pad cavity 189DP may be formed as a single continuous volume derived from merging of laterally-expanded portions of the dummy via cavities 189D′ at the level of the first dielectric bonding material layer 186.

Referring to FIGS. 51 and 5J, at least one metallic material can be deposited in the first integrated pad-and-via cavities 189I and the first dummy integrated pad-and-via cavities 189DI, and excess portions of the at least one metallic material can be removed from above the horizontal plane including the top surface of the first dielectric bonding material layer 186 by performing a planarization process. In one embodiment, the at least one metallic material may comprise a combination of a conductive metallic barrier material and a metallic fill material. The conductive metallic barrier material may comprise a metallic nitride material such as WN, TiN, TaN, MON, TiC, TaC, and/or WC, and may have thickness in a range from 5 nm to 50 nm, although lesser and greater thicknesses may also be employed. The conductive metallic barrier material may be deposited by physical vapor deposition or by chemical vapor deposition. The metallic fill material comprises a high-conductivity metal such as W, Cu, Al, Mo, Co, Ru, alloys thereof such as Cu—Al, etc. The metallic fill material may be deposited by physical vapor deposition, electroplating, electroless plating and/or chemical vapor deposition. The planarization process that may be employed to remove excess portions of the at least one metallic material from above the horizontal plane including the top surface of the first dielectric bonding material layer 186 may employ chemical mechanical polishing.

Each remaining portion of the at least one metallic material that fills a respective first integrated pad-and-via cavity 189I constitutes a first integrated pad-and-via bonding structure 190I, which is a type of a first metallic bonding structure 190. Each remaining portion of the at least one metallic material that fills a respective first dummy integrated pad-and-via cavity 189DI constitutes a first dummy integrated pad-and-via bonding structure 190DI, which is a type of a first dummy metallic bonding structure 190D. Each of the first integrated pad-and-via bonding structures 190I electrically contacts the first topmost metal interconnect structures 148, while each of the first dummy metallic bonding structure 190D do not electrically contact any underlying interconnect structures 140. In one embodiment, each of the first integrated pad-and-via bonding structures 190I comprises a combination of a first metallic barrier liner 190B (which is a patterned portion of the conductive metallic barrier material) and a first metallic fill material portion 190F (which is a patterned portion of the metallic fill material). In one embodiment, each of the first dummy integrated pad-and-via bonding structures 190DI comprises a combination of a first metallic barrier liner 190B (which is a patterned portion of the conductive metallic barrier material) and a first metallic fill material portion 190F (which is a patterned portion of the metallic fill material).

In one embodiment, each of the first integrated pad-and-via bonding structures 190I comprises a respective metallic via portion 190V that is laterally surrounded by the first silicate glass layer 184 and a respective metallic pad portion 190P that is laterally surrounded by the first dielectric bonding material layer 186. In one embodiment, each of the first dummy integrated pad-and-via bonding structures 190DI comprises a respective dummy metallic via portion 190DV that is laterally surrounded by the first silicate glass layer 184 and a respective plurality of metallic pad portions 190DP that are laterally surrounded by the first dielectric bonding material layer 186. In one embodiment, bottom surfaces of the metallic pad portions 190P of the first integrated pad-and-via bonding structures 190I may be formed within a horizontal plane including an interface between the first silicate glass layer 184 and the first dielectric bonding material layer 186 (which may be a first silicon carbide nitride layer). In one embodiment, bottom surfaces of the dummy metallic pad portions 190DP of the first dummy integrated pad-and-via bonding structures 190DI may be formed within a horizontal plane including an interface between the first silicate glass layer 184 and the first dielectric bonding material layer 186 (which may be the first silicon carbide nitride layer).

In one embodiment, at least one of the first integrated pad-and-via bonding structures 190I may comprise a respective first metallic barrier liner 190B that contacts a top surface of the first topmost metal interconnect structures 148, a sidewall of the first silicate glass layer 184, a horizontal surface of the first silicate glass layer 184, and a sidewall of the first dielectric bonding material layer 186 (which may be a first silicon carbide nitride layer). In one embodiment, the first bonding-level dielectric layer 180 further comprises a first etch-stop dielectric layer 182 that underlies the first silicate glass layer 184 and contacting, and laterally surrounding, the first metallic barrier liner 190B. In one embodiment, at least one of the first dummy integrated pad-and-via bonding structures 190DI, may comprise a respective first metallic barrier liner 190B that does not contact any first interconnects 140, but contacts a sidewall of the first silicate glass layer 184, a horizontal surface of the first silicate glass layer 184, and a sidewall of the first dielectric bonding material layer 186 (which may be the first silicon carbide nitride layer).

In one embodiment, the first integrated pad-and-via bonding structures 190I and the first dummy integrated pad-and-via bonding structures 190DI comprise a same set of materials. For example, each may comprise a metal nitride barrier liner 190B and a copper or copper alloy fill material portion 190F.

Referring to FIG. 5K, a second semiconductor die 200 may be provided. The second semiconductor die comprises a second substrate 208, second semiconductor devices 220 formed over, on, and/or in, the second substrate 208, second dielectric material layers 230 that are formed over the second semiconductor devices 220 and embedding second metal interconnect structures 240, and a second bonding-level dielectric layer 280 that is formed over the second dielectric material layers 230. The second substrate 208 may comprise any substrate that may be employed for the first substrate 108. The second semiconductor devices 220 may comprise any type of semiconductor devices known in the art. In one embodiment, the first semiconductor devices 120 may comprise a memory array and the second semiconductor devices 220 may comprise a peripheral circuit configured to control operation of the memory array, or vice versa. The second metal interconnect structures 240 may be electrically connected to the second semiconductor devices 220.

In one embodiment, the second integrated pad-and-via bonding structures 290I and the second dummy integrated pad-and-via bonding structures 290DI comprise a same set of materials. For example, each may comprise a metal nitride barrier liner 290B and a copper or copper alloy fill material portion 290F.

Second topmost metal interconnect structures 248, which are a subset of the second metal interconnect structures 240, are illustrated in FIG. 5K. In one embodiment, the second topmost metal interconnect structures 248 may be arranged in a pattern of a rectangular array or in a pattern of a hexagonal array. In one embodiment, the pattern of the second topmost metal interconnect structures 248 may be a mirror image pattern of the pattern of the first integrated pad-and-via bonding structures 190I.

The second bonding-level dielectric layer 280 comprises a second etch-stop dielectric layer 282, a second silicate glass layer 284, and a second dielectric bonding material layer 286. The second etch-stop dielectric layer 282 comprises a dielectric material that can be employed as an etch-stop structure. For example, the second etch-stop dielectric layer 282 may comprise silicon nitride, silicon carbide, silicon carbide nitride, and/or a dielectric metal oxide. The thickness of the second etch-stop dielectric layer 282 may be in a range from 10 nm to 50 nm, although lesser and greater thicknesses may also be employed. The second silicate glass layer 284 comprises a silicate glass material such as undoped silicate glass or a doped silicate glass.

The processing steps described with reference to FIGS. 5A-5J may be performed with any needed changes on the second semiconductor die 200 to form second integrated pad-and-via bonding structures 290I through the second bonding-level dielectric layer 280 and to form second dummy integrated pad-and-via bonding structures 290DI in an upper portion of the second bonding-level dielectric layer 280. The second integrated pad-and-via bonding structures 290I are second metallic bonding structures 290. The second dummy integrated pad-and-via bonding structures 290DI are second dummy metallic bonding structures 290D. In one embodiment, each of the second integrated pad-and-via bonding structures 290I comprises a combination of a second metallic barrier liner 290B (which is a patterned portion of a conductive metallic barrier material) and a second metallic fill material portion 290F (which is a patterned portion of a metallic fill material). In one embodiment, each of the second integrated pad-and-via bonding structures 290I comprises a respective metallic via portion 290V that is laterally surrounded by the second silicate glass layer 284 and a respective metallic pad portion 290P that is laterally surrounded by the second dielectric bonding material layer 286. In one embodiment, bottom surfaces of the metallic pad portions 290P of the second integrated pad-and-via bonding structures 290I may be formed within a horizontal plane including an interface between the second silicate glass layer 284 and the second dielectric bonding material layer 286 (which may be a second silicon carbide nitride layer).

In one embodiment, at least one of the second integrated pad-and-via bonding structures 290I may comprise a respective second metallic barrier liner 290B that contacts a top surface of a second interconnect 240 (e.g., 248), a sidewall of the second silicate glass layer 284, a horizontal surface of the second silicate glass layer 284, and a sidewall of the second dielectric bonding material layer 286 (which may be a second silicon carbide nitride layer). The second dummy integrated pad-and-via bonding structures 290DI do not electrically contact any second interconnect 240. In one embodiment, the second bonding-level dielectric layer 280 comprises a second etch-stop dielectric layer 282 that underlies the second silicate glass layer 284 and contacting and laterally surrounding the second metallic barrier liner 290B.

Referring to FIG. 5L, the second metallic bonding structures 290 (which may comprise second integrated pad-and-via bonding structures 290I) can be bonded to the first integrated pad-and-via bonding structures 190I by metal-to-metal bonding. Further, the second dummy metallic bonding structures 290D (which may comprise second dummy integrated pad-and-via bonding structures 290DI) can be bonded to the first dummy integrated pad-and-via bonding structures 190DI by metal-to-metal bonding. In one embodiment, the second metallic bonding structures 290 (which may comprise second integrated pad-and-via bonding structures 290I) can be bonded to the first integrated pad-and-via bonding structures 190I by copper-to-copper bonding, which is a metal-to-metal bonding between at least one pair of copper pads. In this case, the first metallic fill material portions 190F and the second metallic fill material portion 290F may consist essentially of copper. In one embodiment, the second dummy metallic bonding structures 290D (which may comprise second dummy integrated pad-and-via bonding structures 290DI) can be bonded to the first dummy integrated pad-and-via bonding structures 190DI by copper-to-copper bonding, which is a metal-to-metal bonding between at least one pair of copper pads.

In one embodiment, a dielectric-to-dielectric bonding may be performed between the second bonding-level dielectric layer 280 and the first dielectric bonding material layer 186 in addition to the metal-to-metal bonding. Generally, each of the second dielectric bonding material layer 286 and the first dielectric bonding material layer 186 comprises and/or consists essentially of a respective dielectric material that may be employed for dielectric-to-dielectric bonding. In one embodiment, the first dielectric bonding material layer 186 comprises and/or consists essentially of silicon carbide nitride.

In one embodiment, the first metallic bonding structures 190 comprise first metallic via portions 190V, and the first dummy metallic bonding structures 190D comprise first dummy metallic via portions 190DV having a lesser height than the first metallic via portions 190V. In one embodiment, all top peripheries of the first metallic via portions 190V and all top peripheries of the first dummy metallic via portions 190DV are located within a horizontal plane.

In one embodiment, each of the first metallic bonding structures 190 comprises a respective first metallic pad portion 190P that is connected to a respective one of the first metallic via portions 190V, and each of the first dummy metallic bonding structures 190D comprise a respective first dummy metallic pad portion 190DP that is connected to a respective subset of the first dummy metallic via portions 190DV, which may comprise a respective plurality of first dummy metallic via portions 190DV.

In one embodiment, the first metallic pad portions 190P and the first dummy metallic pad portions 190DP have a same height as a thickness of the first dielectric bonding material layer 186. In one embodiment, the first dielectric bonding material layer 186 comprise a first silicon carbide nitride layer that is bonded to a second dielectric bonding material layer 286 in the second semiconductor die 200 via dielectric-to-dielectric bonding.

In one embodiment, each of the first dummy metallic via portions 190DV has a respective maximum lateral dimension that is less than ⅓ of a maximum lateral dimension of one of the first metallic via portions 190V. In one embodiment, the respective subset of the first dummy metallic via portions 190DV comprises a respective two-dimensional array of first dummy metallic via portions 190DV each having a lesser maximum lateral extent than any of the first metallic via portions 190V. In one embodiment, the respective subset of the first dummy metallic via portions 190DV comprises a respective set of two or more first dummy metallic via portions 190DV that are nested inside one another such that each first dummy metallic via portion within the respective set of two or more first dummy metallic via portions 190DV laterally surrounds or is laterally surrounded by any other first dummy metallic via portion within the respective set of two or more first dummy metallic via portions 190DV.

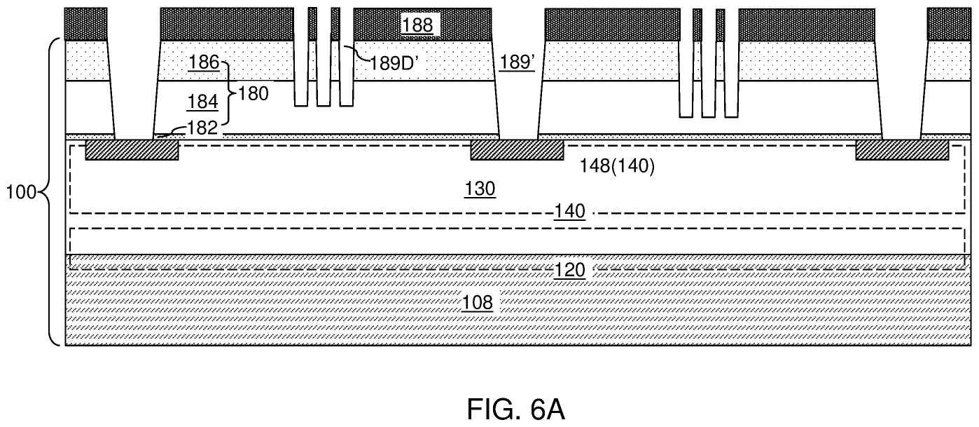

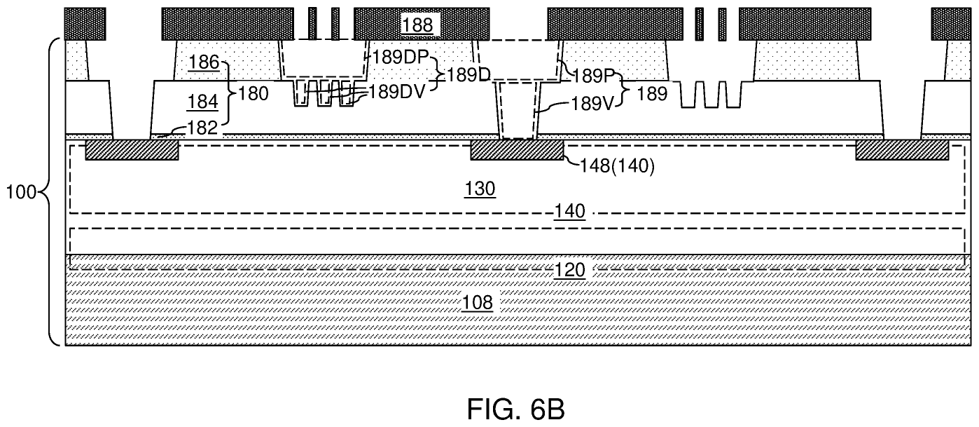

FIGS. 6A and 6B are sequential vertical cross-sectional views of a sixth exemplary structure during formation of the first semiconductor die 100 according to an embodiment of the present disclosure.

Referring to FIG. 6A, the sixth exemplary structure can be derived from the first exemplary structure illustrated in FIG. 5D by selecting the thickness of the first dielectric bonding material layer 186 to be the same as the final thickness of the first dielectric bonding material layer 186 after the processing steps of FIGS. 5F, 5G, and 5H. The hard mask layer 188 may be the same as described with reference to FIGS. 5A-5C. The anisotropic etch process described with reference to FIG. 5D can be performed to form via cavities 189′ and dummy via cavities 189D′.

Referring to FIG. 6B, the selective etch process described with reference to FIGS. 5F-5H can be performed to convert the via cavities 189′ into first integrated pad-and-via cavities 189I and to convert the dummy via cavities 189D′ into first dummy integrated pad-and-via cavities 189DI while the hard mask layer 188 is present on the top surface of the first dielectric bonding material layer 186. Each first integrated pad-and-via cavity 189I may comprise a respective via cavity 189V that is laterally surrounded by the first silicate glass layer 184 and further comprises a respective pad cavity 189P that is laterally surrounded by the first dielectric bonding material layer 186.

Each first dummy integrated pad-and-via cavity 189DI may comprises a respective dummy via cavity 189DV that is laterally surrounded by the first silicate glass layer 184 and further comprises a respective set of dummy pad cavities 189DP that are laterally surrounded by the first dielectric bonding material layer 186. In this case, the thickness of the first dielectric bonding material layer 186 remains unchanged during the selective etch process.

Subsequently, the hard mask layer 188 can be removed selective to the first dielectric bonding material layer 186, the first silicate glass layer 184, the first etch-stop dielectric layer 182, and the first topmost metal interconnect structures 148, for example, by ashing.

The processing steps described with respect to FIGS. 5I, 5J, 5K, and 5L can be subsequently performed to form a first semiconductor die 100 including first integrated pad-and-via bonding structures 190I, to provide a second semiconductor die 200, and to form a bonded assembly of the first semiconductor die 100 and the second semiconductor die 200. The bonded assembly may be the same as the bonded assembly illustrated in FIG. 5L.

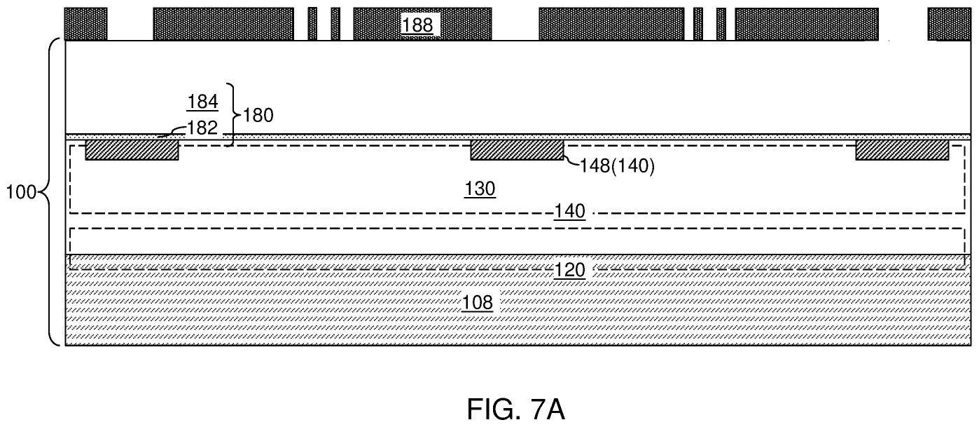

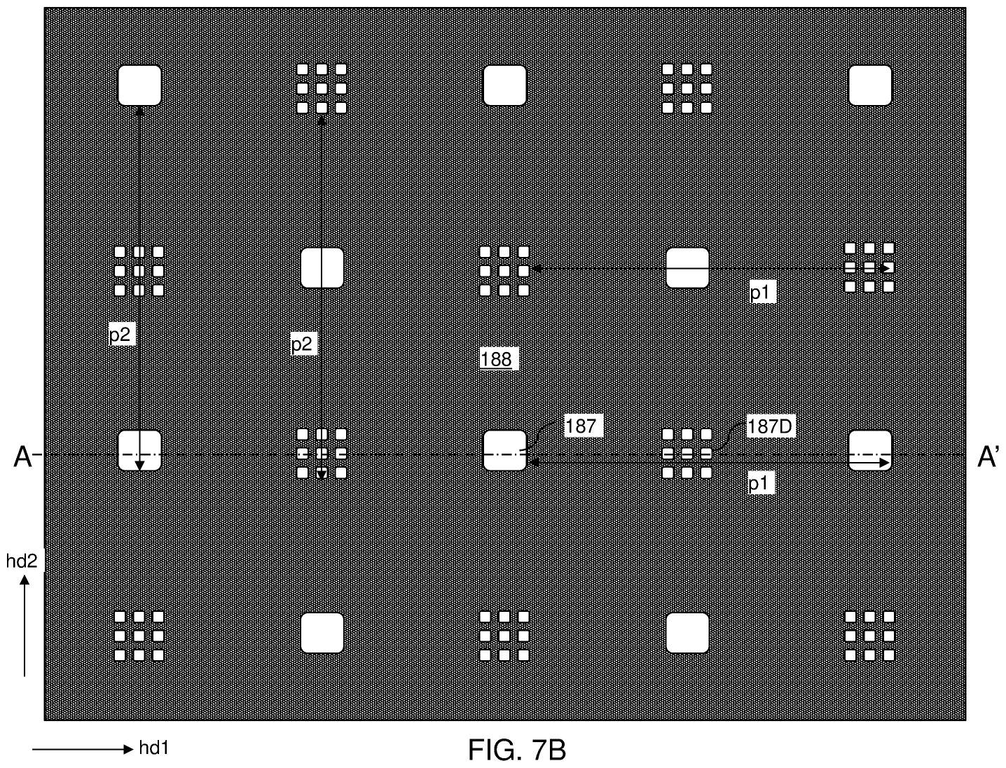

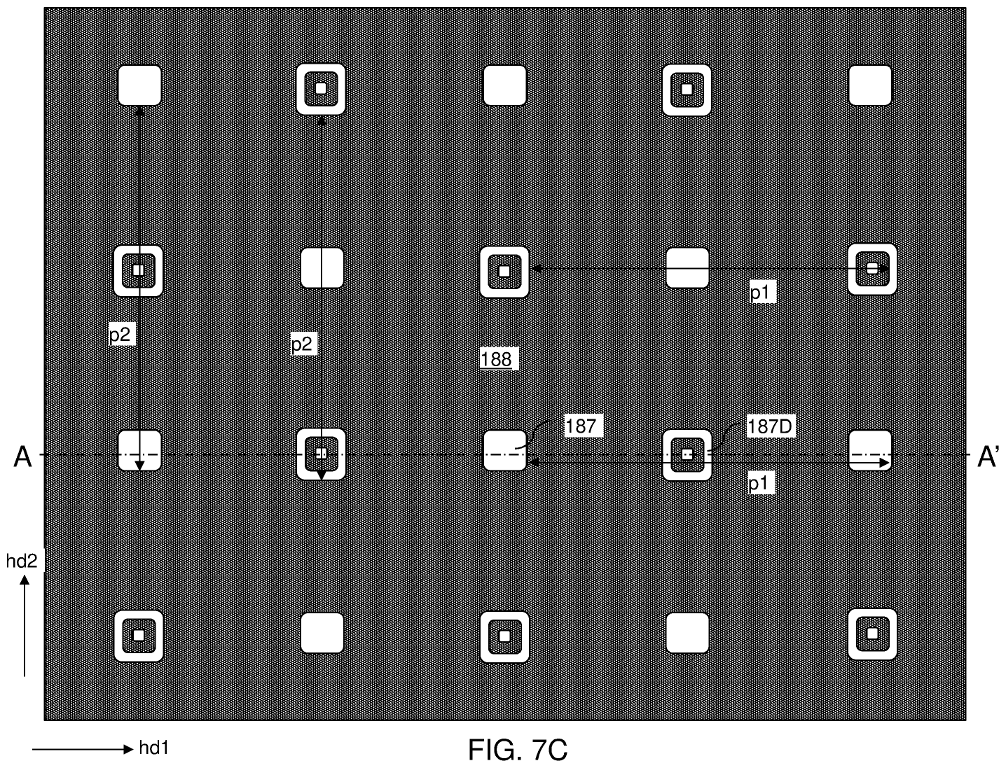

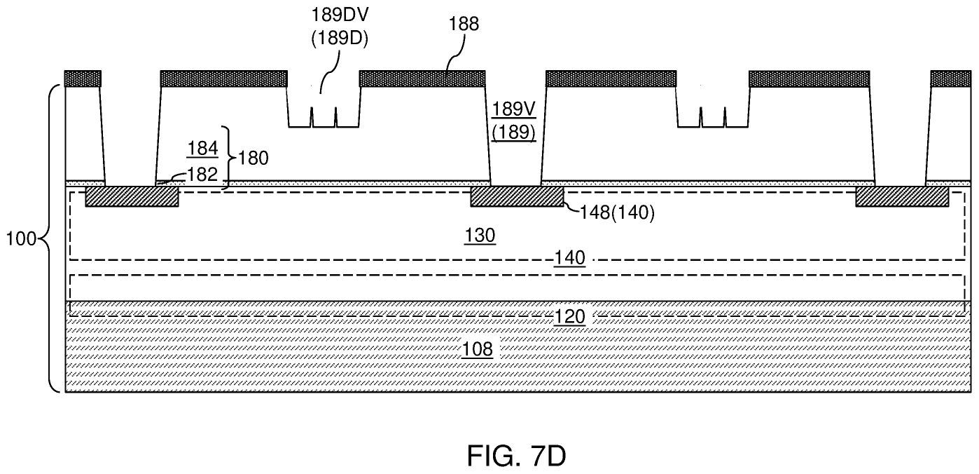

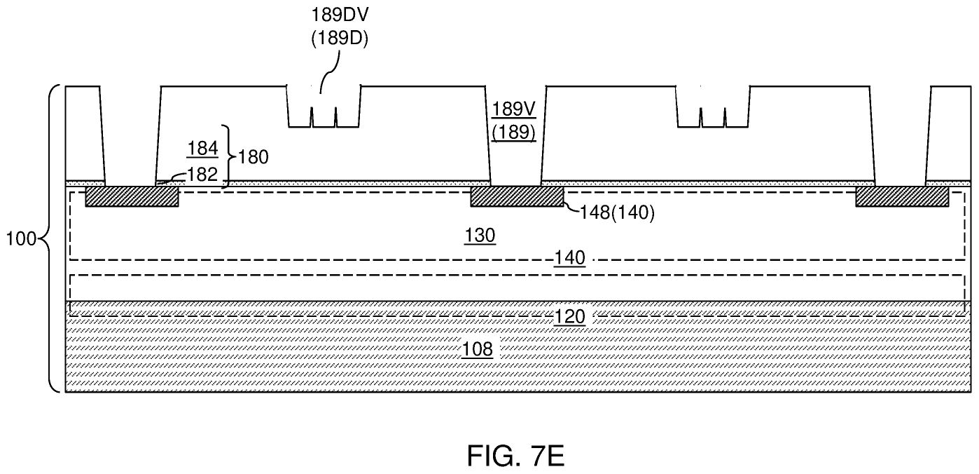

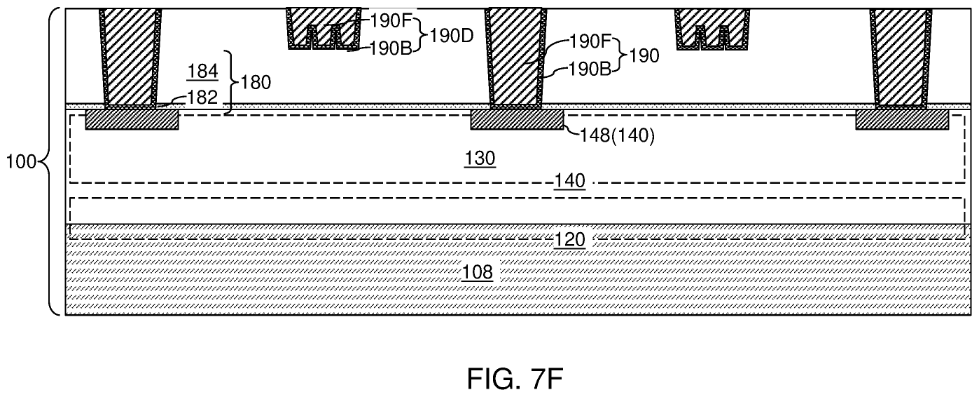

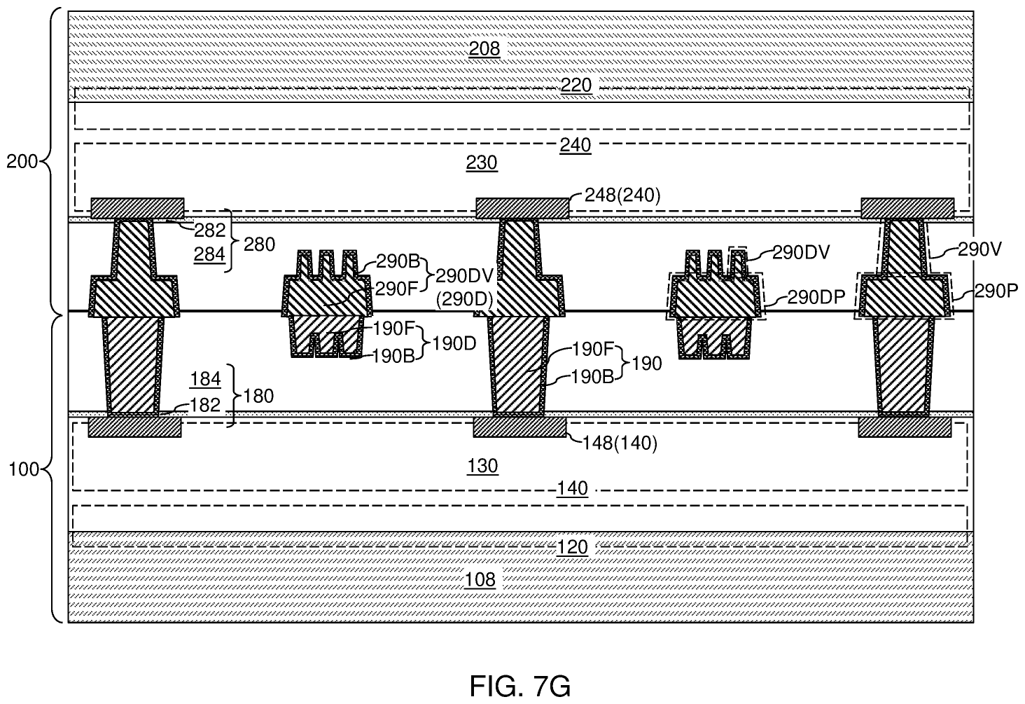

Referring to FIGS. 7A, 7B, 7C, a seventh exemplary structure according to an embodiment of the present disclosure is illustrated. The seventh exemplary structure may be derived from the fifth exemplary structure illustrated in FIGS. 5A, 5B, and 5C by omitting the first dielectric bonding material layer 186 from the first bonding-level dielectric layer 180. The hard mask layer 188 may be the same as described with reference to FIGS. 5A-5C. Thus, the hard mask layer 188 with a composite pattern that includes a pattern of via openings 187 and a pattern of dummy via openings 187D. The hard mask layer 188 may be formed on the top surface of the first silicate glass layer 184.

Referring to FIG. 7D, an anisotropic etch process described above with respect to FIG. 5D can be performed to transfer the pattern of the openings in the hard mask layer 188 into the first bonding-level dielectric layer 180. Via cavities 189V and dummy via cavities 189DV are formed in the first bonding-level dielectric layer 180, as described above. Each via cavity 189V of the seventh exemplary structure consists of a via cavity portion, and does not include any pad cavity portion. Each via cavity 189V of the seventh exemplary structure is a type of a via cavity 189. In one embodiment, cavities that are formed underneath a cluster of dummy via openings 187D can be merged to form a continuous volume of a void, which constitutes a respective one of the dummy via cavities 189DV. Each dummy via cavity 189DV in the seventh exemplary structure is a type of dummy via cavities 189D.

Referring to FIG. 7E, the hard mask layer 188 is removed from the first bonding-level dielectric layer 180, as described above.

Referring to FIG. 7F, at least one metallic material can be deposited in the via cavities 189V and the dummy via cavities 189DV, and excess portions of the at least one metallic material can be removed from above the horizontal plane including the top surface of the first dielectric bonding material layer 186 by performing a planarization process, as described above.

Each remaining portion of the at least one metallic material that fills a respective via cavity 189V constitutes a first metallic bonding structure 190. Each remaining portion of the at least one metallic material that fills a respective dummy via cavity 189DV constitutes a first dummy metallic bonding structure 190D. In one embodiment, each of the first metallic bonding structures 190 comprises a combination of a first metallic barrier liner 190B (which is a patterned portion of the conductive metallic barrier material) and a first metallic fill material portion 190F (which is a patterned portion of the metallic fill material). The first metallic bonding structures 190 comprise via only bonding structures, which lack a pad portion.

Referring to FIG. 7G, the second semiconductor die 200 may be provided as described above. The second metallic bonding structures 290 may comprise via only bonding structures similar to the first metallic bonding structures 190. Alternatively, the second metallic bonding structures 290 may comprise a pad-and-via bonding structures (290P, 290V). The second semiconductor die 200 is bonded to the first semiconductor die 100 as described above to form the bonded assembly.

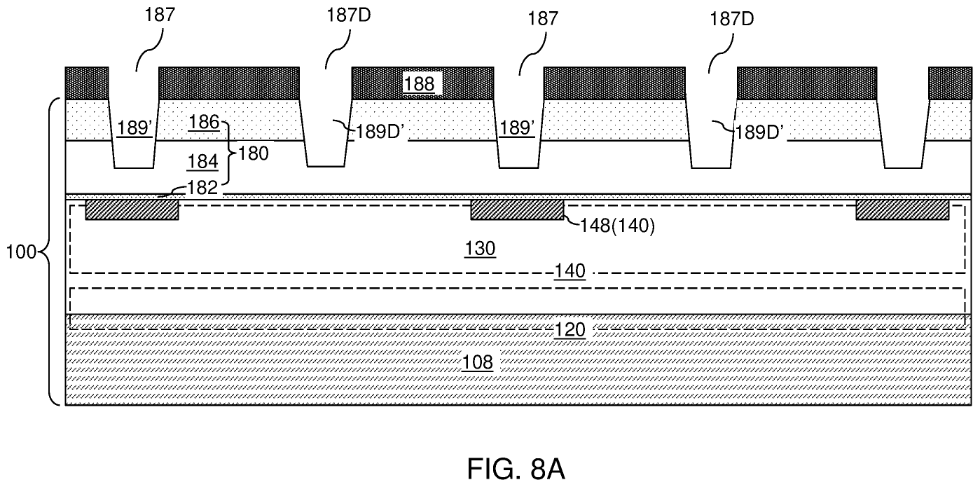

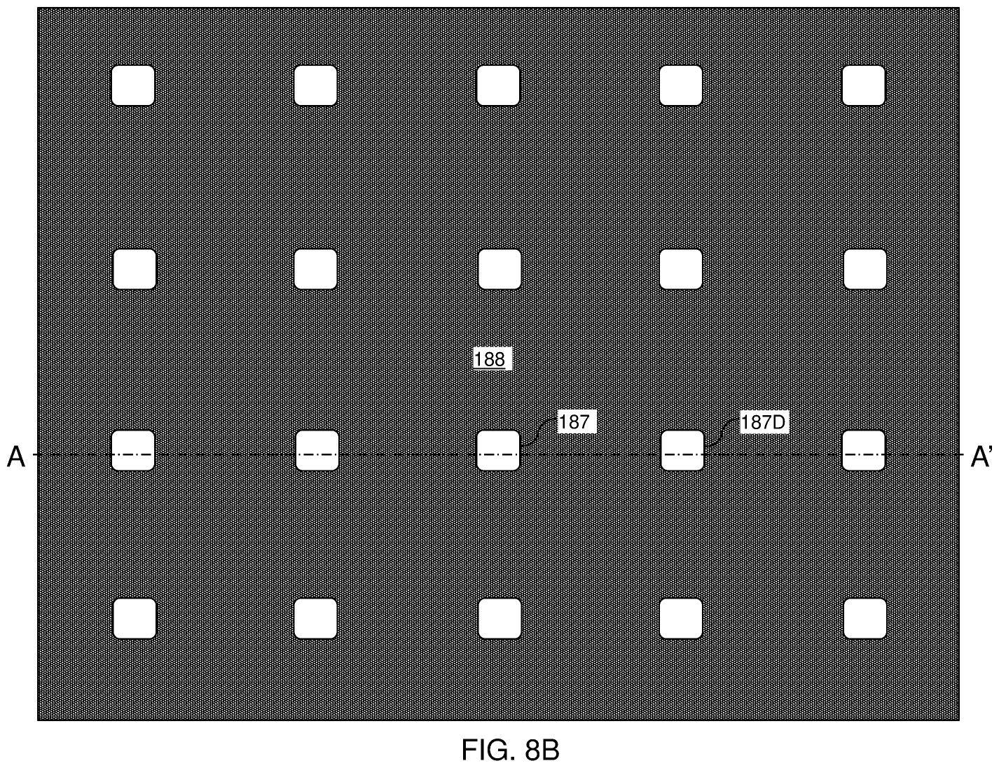

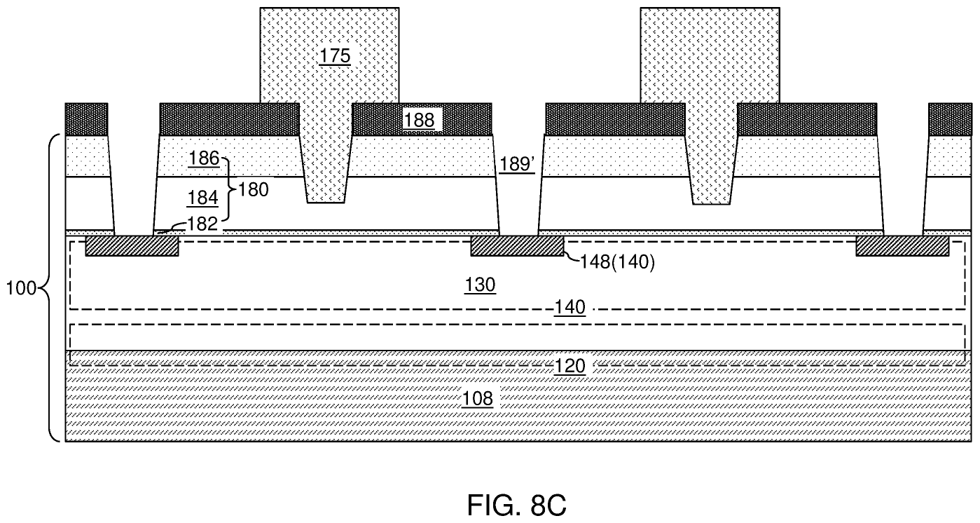

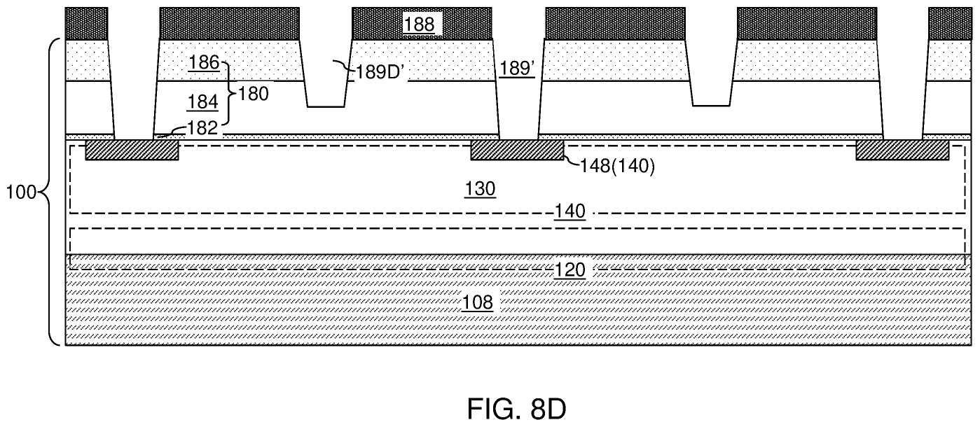

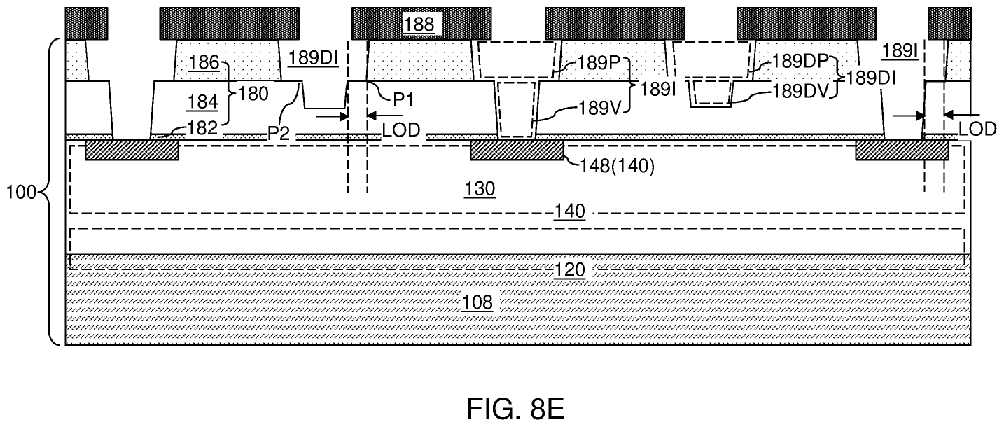

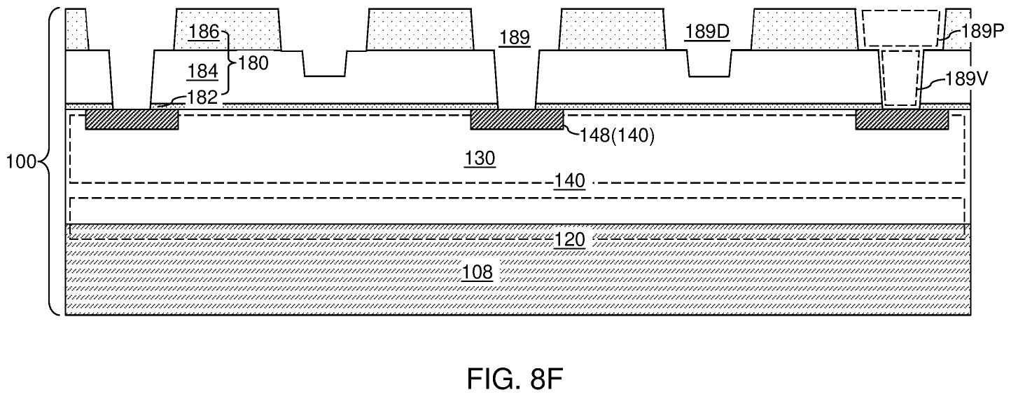

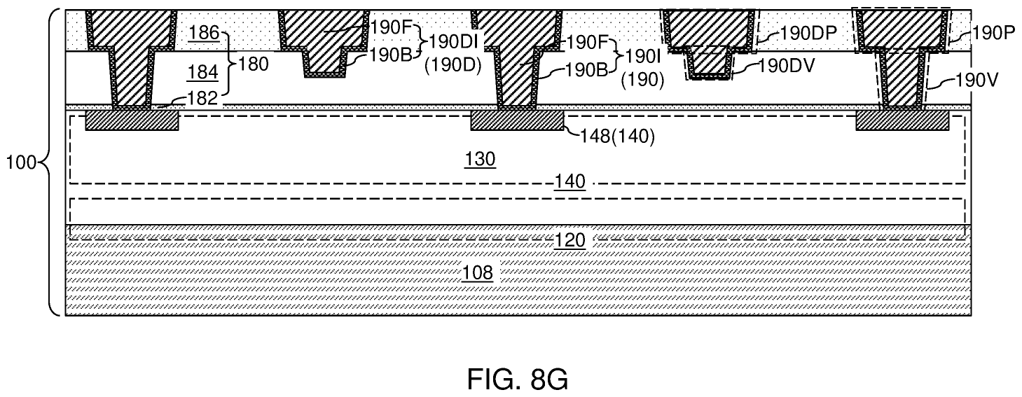

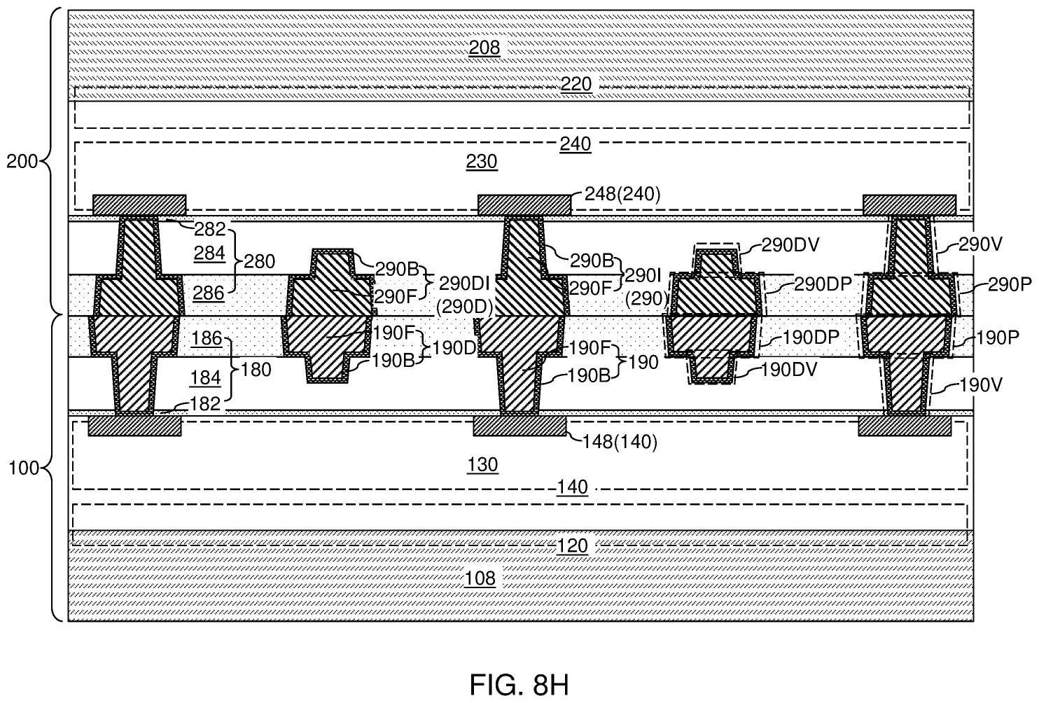

Referring to FIGS. 8A and 8B, an eighth exemplary structure can be derived from the seventh exemplary structure illustrated in FIGS. 5A and 5B by modifying the pattern of the dummy via openings 187D. Specifically, a single dummy via opening 187D having a comparable horizontal cross-sectional shape to a via opening 187 is formed in each unit area of a second two-dimensional array of dummy via openings 187D in lieu of a plurality of dummy via openings 187D. Each dummy via opening 187D may have horizontal cross-sectional area that is within 20% of the horizontal cross-sectional area of each via opening 187.

Subsequently, an anisotropic etch process can be performed to transfer the pattern of the openings in the hard mask layer 188 through the first dielectric bonding material layer 186 and into an upper portion of the first silicate glass layer 184. Via cavities 189′ are formed underneath the via openings 187 in the hard mask layer 188, and dummy via cavities 189D′ are formed underneath the dummy via openings 187D in the hard mask layer 188. In one embodiment, the via cavities 189′ and the dummy via cavities 189D′ may have the same or similar (e.g., within 20% of each other), lateral dimensions, and may have the same or similar (e.g., within 20% of each other) depths.

Referring to FIG. 8C, a photoresist layer 175 can be applied over the hard mask layer 188, and can be lithographically patterned to fill the dummy via cavities 189D′ without covering the via cavities 189′. An additional anisotropic etch process can be performed to vertically extend the via cavities 189′ through a lower portion of the first silicate glass layer 184 and the first etch-stop dielectric layer 182 to expose a top surface of a respective first topmost metal interconnect structure 148. After the additional anisotropic etch process, each of the via cavities 189′ comprises a respective straight sidewall that extends through an entirety of the second silicate glass layer 284 and through an entirety of the second dielectric bonding material layer 286. In one embodiment, the straight sidewall of at least one of the via cavities 189′ may vertically extend from the topmost surface of the first dielectric bonding material layer 186 to a surface of a respective first topmost metal interconnect structure 148.

Referring to FIG. 8D, the photoresist layer 175 can be removed, for example, by ashing.

Referring to FIG. 8E, a selective etch process can be performed to recess the material of the first dielectric bonding material layer 186 selective to the materials of the first silicate glass layer 184, the first etch-stop dielectric layer 182, and the first topmost metal interconnect structures 148, as described above with respect to FIG. 6B. The via cavities 189′ can be converted into first integrated pad-and-via cavities 189I by performing a selective etch process that etches the material of the first dielectric bonding material layer 186 selective to the material of the first silicate glass layer 184. Each of the first integrated pad-and-via cavities 189I comprises a respective via cavity 189V that is laterally surrounded by the first silicate glass layer 184 and further comprises a respective pad cavity 189P that is laterally surrounded by the first dielectric bonding material layer 186.

The dummy via cavities 189D′ can be converted into first dummy integrated pad-and-via cavities 189DI by performing the selective etch process. Each of the first dummy integrated pad-and-via cavities 189DI comprises a respective dummy via cavity 189DV that is laterally surrounded by the first silicate glass layer 184 and further comprises a respective dummy pad cavity 189DP that is laterally surrounded by the first dielectric bonding material layer 186.

In one embodiment, at least one of the first dummy integrated pad-and-via cavities 189DI may comprise a respective third sidewall which is a sidewall of the first dielectric bonding material layer 186, a respective fourth sidewall which is a sidewall of the first silicate glass layer 184, and a horizontal connecting surface that connects a bottom periphery (which is referred to as a third periphery) of the respective third sidewall and a top periphery (which is referred to as a fourth periphery) of the respective fourth sidewall. According to an aspect of the present disclosure, the selective etch process is isotropic, and thus, the third periphery may be laterally offset outward from the fourth periphery by the uniform lateral offset distance LOD.

Referring to FIG. 8F, the hard mask layer 188 can be removed selective to the materials of the first dielectric bonding material layer 186, the first silicate glass layer 184, the first etch-stop dielectric layer 182, and the first topmost metal interconnect structures 148.

Referring to FIG. 8G, at least one metallic material can be deposited in the first integrated pad-and-via cavities 189I and the first dummy integrated pad-and-via cavities 189DI, and excess portions of the at least one metallic material can be removed from above the horizontal plane including the top surface of the first dielectric bonding material layer 186 by performing a planarization process, as described above.

Each remaining portion of the at least one metallic material that fills a respective first integrated pad-and-via cavity 189I constitutes a first integrated pad-and-via bonding structure 190I, which is a first metallic bonding structure 190. Each remaining portion of the at least one metallic material that fills a respective first dummy integrated pad-and-via cavity 189DI constitutes a first dummy integrated pad-and-via bonding structure 190DI, which is a first dummy metallic bonding structure 190D. In one embodiment, each of the first integrated pad-and-via bonding structures 190I comprises a combination of a first metallic barrier liner 190B (which is a patterned portion of the conductive metallic barrier material) and a first metallic fill material portion 190F (which is a patterned portion of the metallic fill material).

Referring to FIG. 8H, the second semiconductor die 200 may be provided as described above. The processing steps described with reference to FIGS. 8A-8G may be performed with any needed change on the second semiconductor die 200 to form second integrated pad-and-via bonding structures 290I and second dummy integrated pad-and-via bonding structures 290DI. The second integrated pad-and-via bonding structures 290I are second metallic bonding structures 290. The second dummy integrated pad-and-via bonding structures 290DI are second dummy metallic bonding structures 290D. In one embodiment, each of the second metallic bonding structures 290 comprises a combination of a second metallic barrier liner 290B (which is a patterned portion of a conductive metallic barrier material) and a second metallic fill material portion 290F (which is a patterned portion of a metallic fill material). In one embodiment, at least one of the second metallic bonding structures 290, may comprise a respective second metallic barrier liner 290B and a second metallic fill material portion 290F. In one embodiment, at least one of the second dummy metallic bonding structures 290D, may comprise a respective second metallic barrier liner 290B and a second metallic fill material portion 290F.

The second metallic bonding structures 290 can be bonded to the first metallic bonding structures 190 by metal-to-metal bonding, as described above. The second dummy metallic bonding structures 290D can be bonded to the first dummy metallic bonding structures 190D by additional metal-to-metal bonding, as described above.

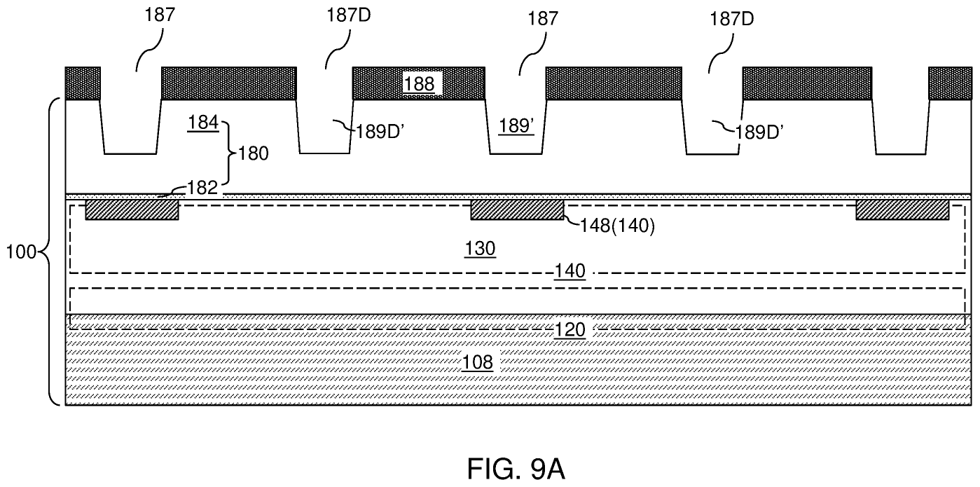

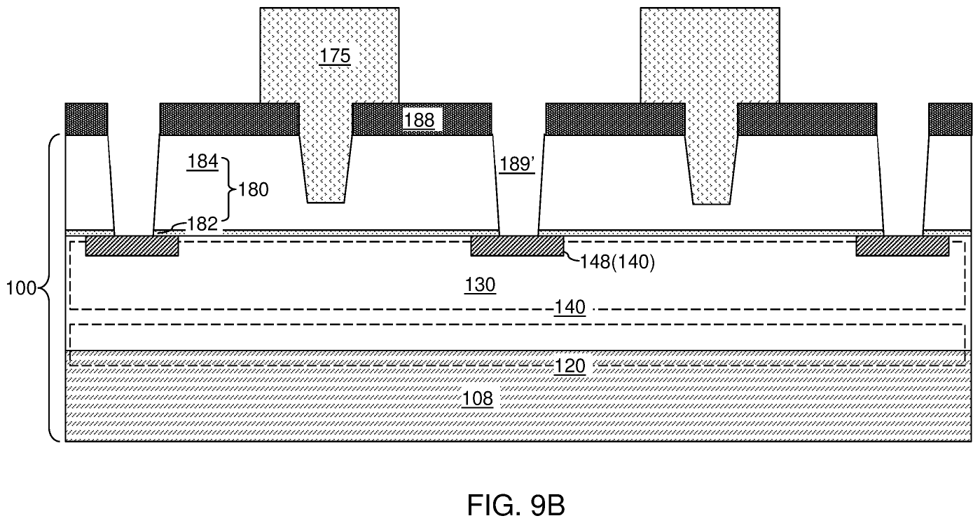

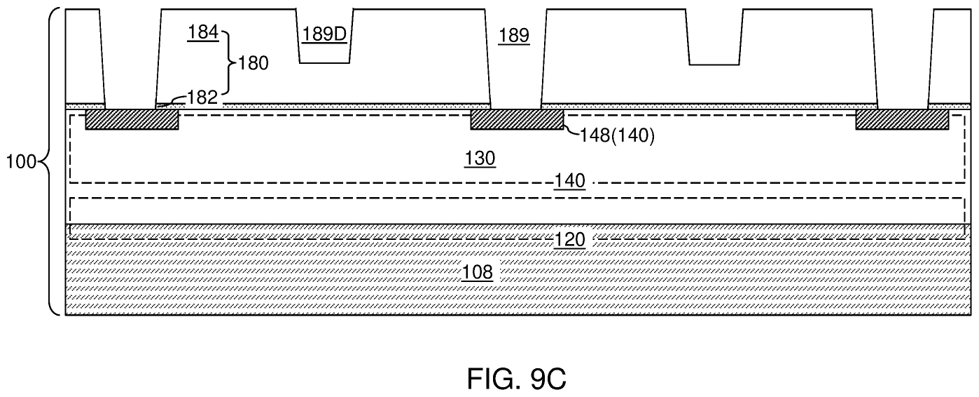

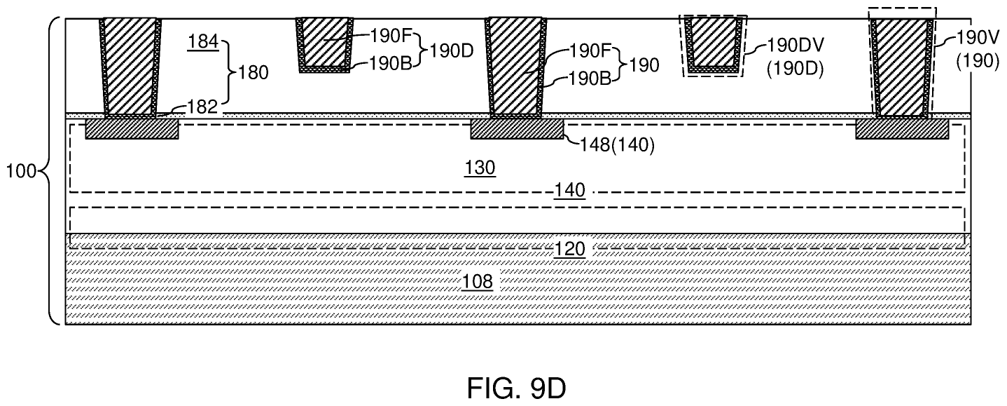

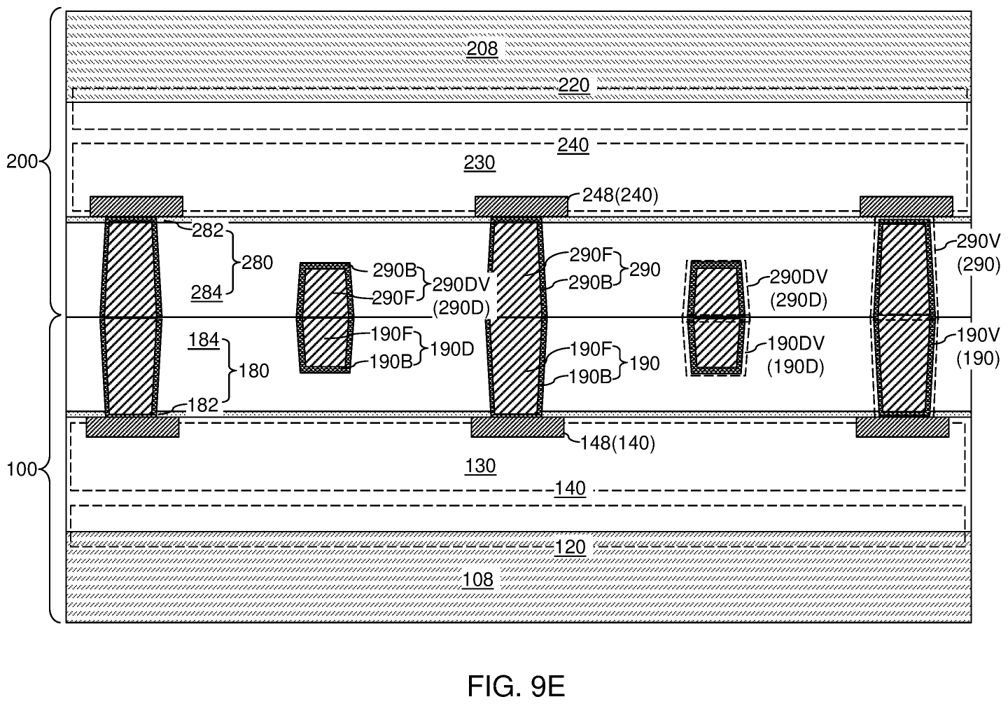

Referring to FIG. 9A, a ninth exemplary structure can be derived from the eighth exemplary structure by omitting the first dielectric bonding material layer 186 and forming a first silicate glass layer 184 in lieu of a stack of a first silicate glass layer 184 and a first dielectric bonding material layer 186 in the first semiconductor die 100 in FIG. 8A. The thickness of the first silicate glass layer 184 in the first semiconductor die 100 in the ninth exemplary structure may be the same as the sum of the thickness of the first silicate glass layer 184 in the eighth exemplary structure and the thickness of the first dielectric bonding material layer 186 in the eighth exemplary structure. Via cavities 189′ are formed underneath the via openings 187 in the hard mask layer 188, and dummy via cavities 189D′ are formed underneath the dummy via openings 187D in the hard mask layer 188. The depths of the via cavities 189′ and the dummy via cavities 180D′ in the ninth exemplary structure may be the same as the depths of the via cavities 189′ and the dummy via cavities 180D′ in the eighth exemplary structure of FIG. 8A.

Referring to FIG. 9B, the processing steps described with reference to FIG. 8C can be performed to cover the dummy via cavities 189D′ with a patterned photoresist layer 175, and to vertically extend the via cavities 189′ through a lower portion of the first silicate glass layer 184 and the first etch-stop dielectric layer 182.

Referring to FIG. 9C, the patterned photoresist layer 175 and the hard mask layer 188 can be removed selective to the first silicate glass layer 184, the first etch-stop dielectric layer 182, and the first topmost metal interconnect structures 148.

Referring to FIG. 9D, at least one metallic material can be deposited in the via cavities 189′ and the dummy via cavities 189D′, and excess portions of the at least one metallic material can be removed from above the horizontal plane including the top surface of first silicate glass layer 184 by performing a planarization process, as described above.

Each remaining portion of the at least one metallic material that fills a respective via cavity 189′ constitutes a first metallic bonding structure 190. Each remaining portion of the at least one metallic material that fills a respective dummy via cavity 189V′ constitutes a first dummy metallic bonding structure 190D. In one embodiment, each of the first metallic bonding structures 190 comprises a combination of a first metallic barrier liner 190B (which is a patterned portion of the conductive metallic barrier material) and a first metallic fill material portion 190F (which is a patterned portion of the metallic fill material). In one embodiment, each of the first metallic bonding structures 190 consists of a respective metallic via portion 190V that is laterally surrounded by the first silicate glass layer 184. In one embodiment, each of the first dummy metallic bonding structures 190D comprises a combination of a first metallic barrier liner 190B (which is a patterned portion of the conductive metallic barrier material) and a first metallic fill material portion 190F (which is a patterned portion of the metallic fill material). In one embodiment, each of the first dummy metallic bonding structures 190D includes only the metallic via portion 190DV having a lesser vertical extent than the first metallic bonding structures 190.

Referring to FIG. 9E, a second semiconductor die 200 may be provided as described above.

The processing steps described with reference to FIGS. 9A-9D may be performed with any needed changes on the second semiconductor die 200 to form second metallic bonding structures 290 and second dummy metallic bonding structures 290D in the second bonding-level dielectric layer 280. In one embodiment, each of the second metallic bonding structures 290 comprises a combination of a second metallic barrier liner 290B (which is a patterned portion of a conductive metallic barrier material) and a second metallic fill material portion 290F (which is a patterned portion of a metallic fill material). In one embodiment, each of the second metallic bonding structures 290 consists of a respective metallic via portion 290V. In one embodiment, at least one of the second dummy metallic bonding structures 290D, may comprise a respective second metallic barrier liner 290B and a second metallic fill material portion 290F. In one embodiment, each of the second dummy metallic bonding structures 290D consists of a respective metallic via portion 290DV.

The second semiconductor die 200 can be bonded to the first semiconductor die 100. Specifically, the second metallic bonding structures 290 can be bonded to the first metallic bonding structures 190 by metal-to-metal bonding. The second dummy metallic bonding structures 290D can be bonded to the first dummy metallic bonding structures 190D by additional metal-to-metal bonding. In one embodiment, the second metallic bonding structures 290 can be bonded to the first metallic bonding structures 190 by copper-to-copper bonding. The second dummy metallic bonding structures 290D can be bonded to the first dummy metallic bonding structures 190D by additional copper-to-copper bonding. In one embodiment, a dielectric-to-dielectric bonding may be performed between the second bonding-level dielectric layer 280 and the first bonding-level dielectric layer 180 in addition to the metal-to-metal bonding.

The dummy metallic bonding structures (190D, 290D) improve the bonding between the first and second semiconductor dies (100, 200) by providing additional bonding points, providing a more uniform bonding pad density, and improving flatness between the bonding pads and the surrounding dielectric material after chemical mechanical polishing. By making the dummy metallic bonding structures (190D, 290D) shallower than respective metallic bonding structures (190, 290), the likelihood of a short circuit between the dummy metallic bonding structures (190D, 290D) and the respective interconnects (140, 240) is reduced. Furthermore, in some embodiments, the shallower dummy metallic bonding structures (190D, 290D) may be formed without using a dedicated etch stop layer on which these structures terminate, which simplifies the manufacturing processes.

Referring collectively to FIGS. 5A-9E, a bonded assembly of a first semiconductor die 100 and a second semiconductor die 200. The first semiconductor die 100 comprises first dielectric material layers 130 located on first semiconductor devices 120; first metal interconnect structures 140 embedded in the first dielectric material layers 130 and electrically connected to the first semiconductor devices 120; and a first bonding-level dielectric layer 180 located on the first dielectric material layers 130 and embedding first metallic bonding structures 190 that are electrically connected to a respective one of the first metal interconnect structures 140, and further embedding first dummy metallic bonding structures 190D having a lesser vertical extent than the first metallic bonding structures 190 and electrically isolated from the first metal interconnect structures 140.

In one embodiment, the first metallic bonding structures 190 comprise first metallic via portions 190V; the first dummy metallic bonding structures 190D comprise first dummy metallic via portions 190DV having a lesser height than the first metallic via portions 190V; and all top peripheries of the first metallic via portions 190V and all top peripheries of the first dummy metallic via portions 190DV are located within a horizontal plane. In one embodiment, the first bonding-level dielectric layer 180 comprises a stack of a first silicate glass layer 184 and a first dielectric bonding material layer 186. In one embodiment, each of the first metallic bonding structures 190 comprise a respective first metallic pad portion that is connected to a respective one of the first metallic via portions 190V; and each of the first dummy metallic bonding structures 190D comprise a respective first dummy metallic pad portion that is connected to a respective subset of the first dummy metallic via portions 190DV.

In one embodiment, a horizontal interface between the first silicate glass layer 184 and the first dielectric bonding material layer 186 is located within the horizontal plane. In one embodiment, the first metallic pad portions and the first dummy metallic pad portions have a same height as a thickness of the first dielectric bonding material layer 186. In one embodiment, the first dielectric bonding material layer 186 comprise a first silicon carbide nitride layer that is bonded to a second dielectric bonding material layer 286 in the second semiconductor die 200 via dielectric-to-dielectric bonding.

In one embodiment, each of the first dummy metallic via portions 190DV has a respective maximum lateral dimension that is less than ⅓ of a maximum lateral dimension of one of the first metallic via portions 190V. In one embodiment, the respective subset of the first dummy metallic via portions 190DV comprises a respective two-dimensional array of first dummy metallic via portions 190DV each having a lesser maximum lateral extent than any of the first metallic via portions 190V. In one embodiment, the respective subset of the first dummy metallic via portions 190DV comprises a respective set of two or more first dummy metallic via portions 190DV that are nested inside one another such that each first dummy metallic via portion within the respective set of two or more first dummy metallic via portions 190DV laterally surrounds, or is laterally surrounded by, any other first dummy metallic via portion within the respective set of two or more first dummy metallic via portions 190DV,

In one embodiment, the first metallic bonding structures 190 consist of first metallic via portions 190V; the first dummy metallic bonding structures 190D consist of first dummy metallic via portions 190DV having a lesser height than the first metallic via portions 190V; and all top peripheries of the first metallic via portions 190V and all top peripheries of the first dummy metallic via portions 190DV are located within a horizontal plane including a bonding interface between the first semiconductor die 100 and the second semiconductor die 200. In one embodiment, the first dielectric bonding material layer 186 comprises a horizontal surface located within the horizontal plane and bonded to a second dielectric bonding material layer 286 within the second semiconductor die 200 by dielectric-to-dielectric bonding.

In one embodiment, the first bonding-level dielectric layer 180 comprises a first silicate glass layer 184 laterally surrounding first metallic via portions 190V and the first dummy metallic via portions 190DV; and wherein a top surface of the first silicate glass layer 184 is located within the horizontal plane. In one embodiment, the first silicate glass layer 184 is bonded to a second dielectric bonding material layer 286 within the second semiconductor die 200 by dielectric-to-dielectric bonding.

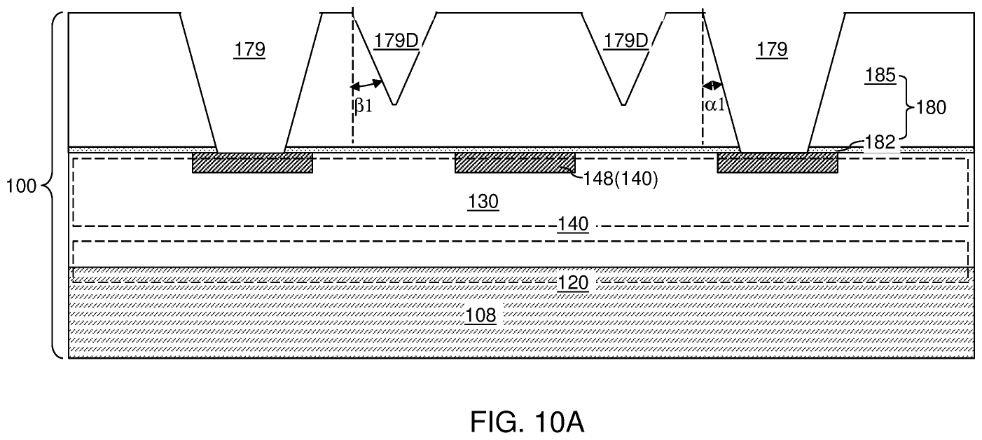

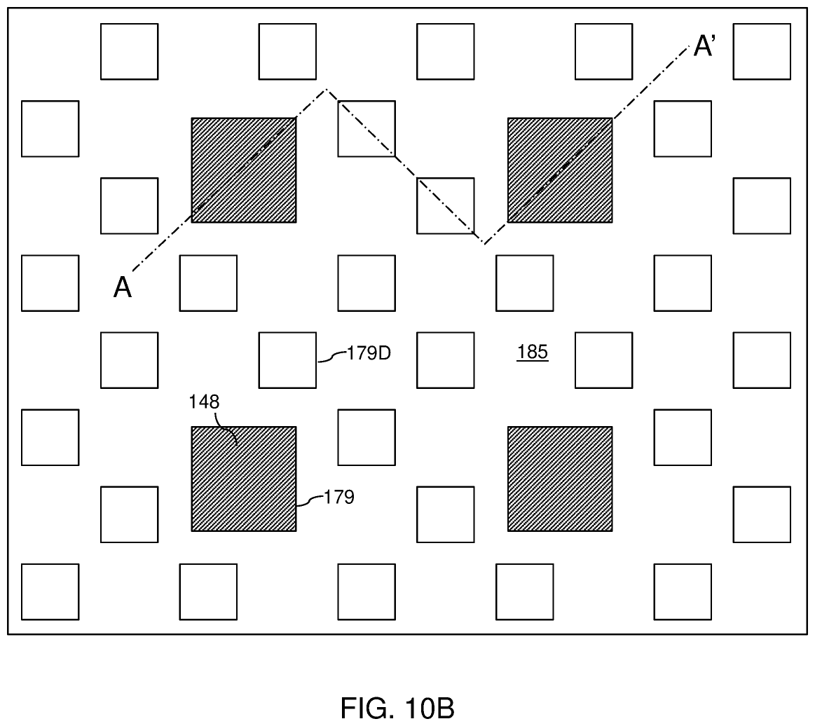

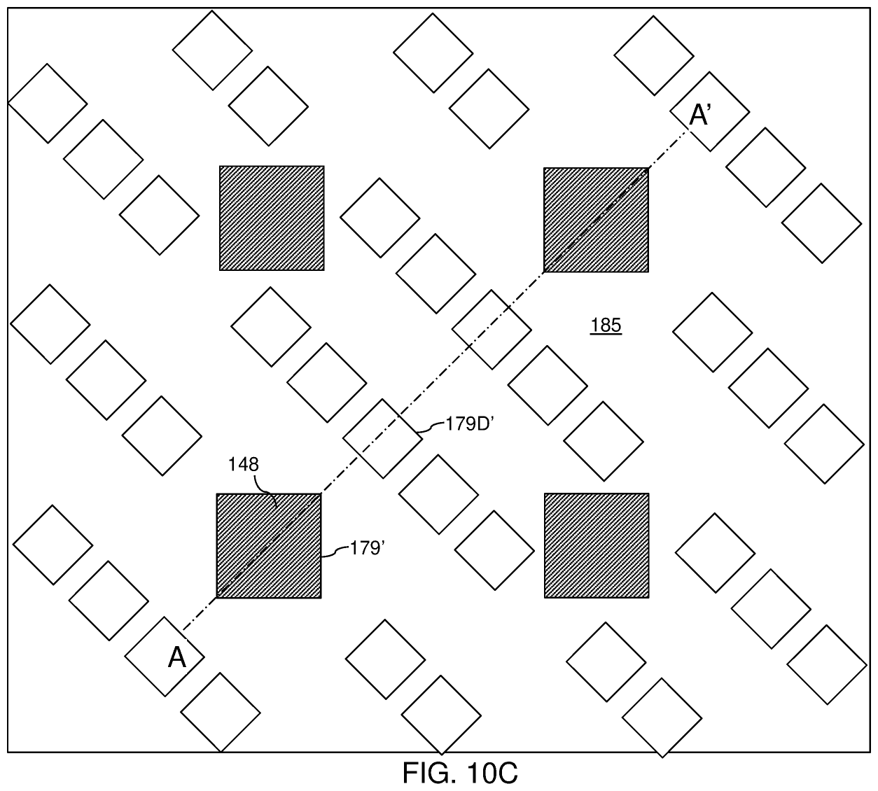

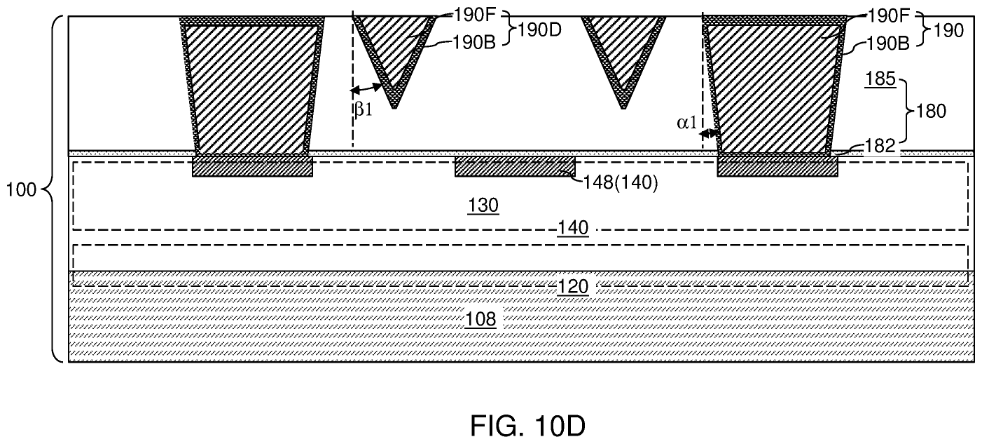

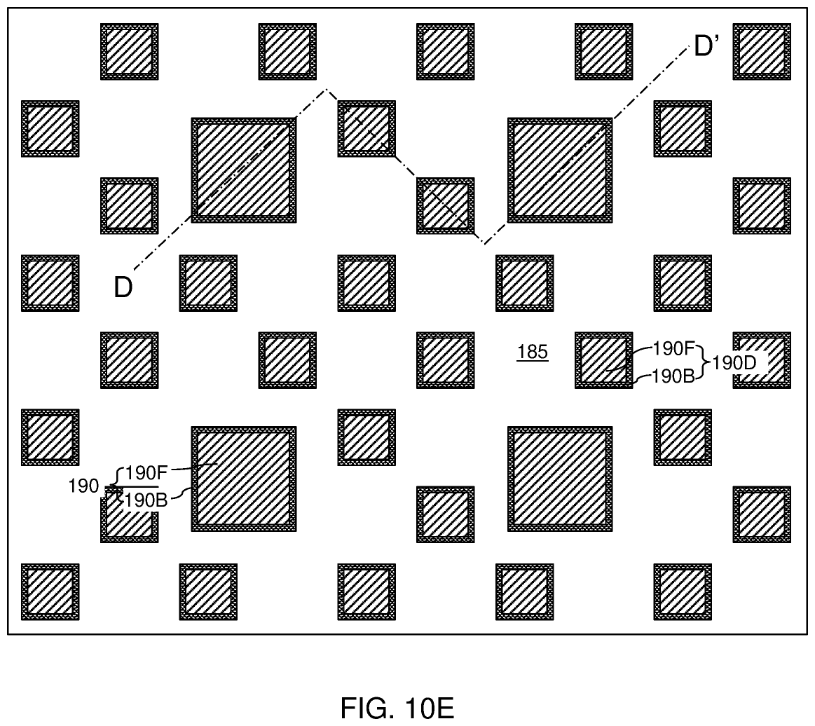

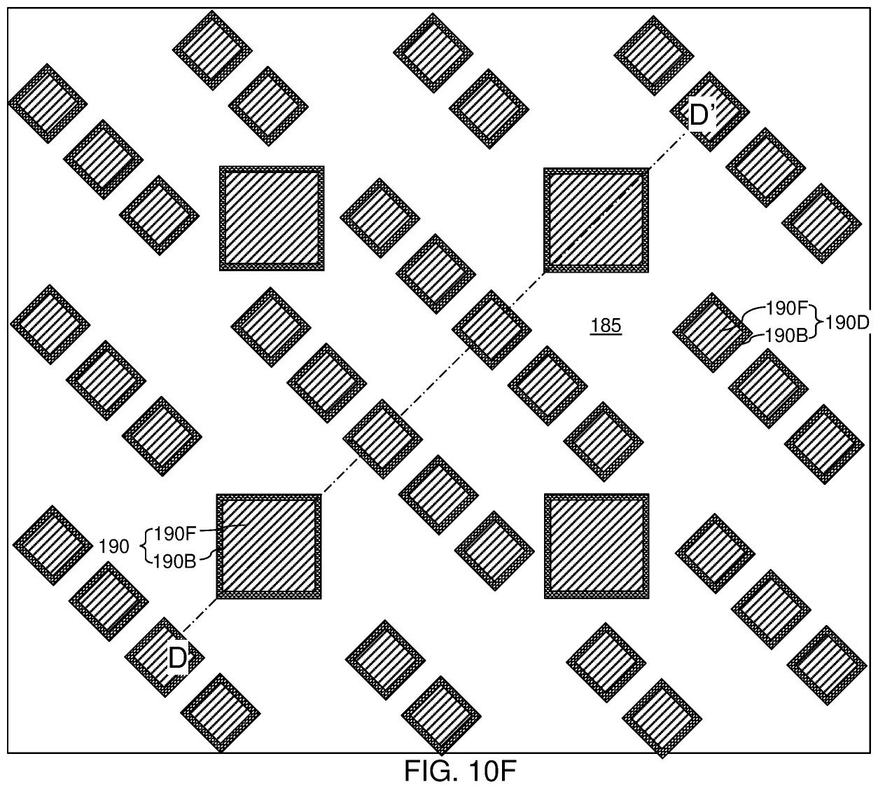

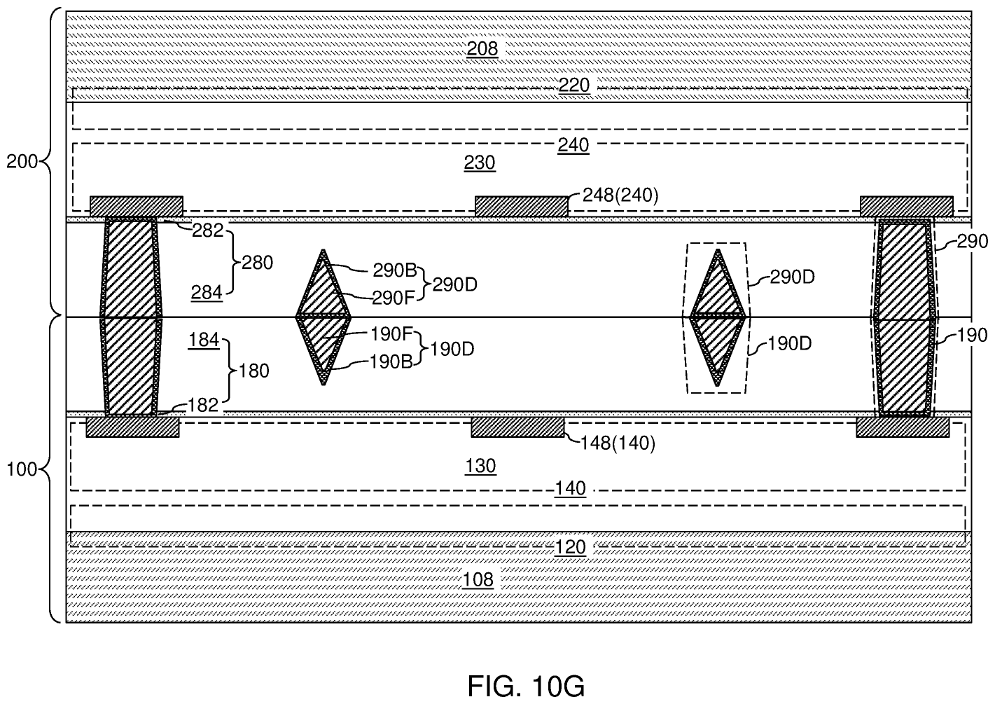

Referring to FIGS. 10A-10C, a tenth exemplary structure comprises a first semiconductor die 100, which can be derived from the first semiconductor die 100 illustrated in FIG. 1A by replacing a combination of a first silicate glass layer 184 and a first dielectric bonding material layer 186 with a first dielectric bonding material layer 185. The first dielectric bonding material layer 185 may comprise any material that may be employed for the first dielectric bonding material layer 186 and the first silicate glass layer 184. For example, the first dielectric bonding material layer 185 may comprise a first silicate glass layer (e.g., doped or undoped silicate glass). The thickness of the first dielectric bonding material layer 185 may be in a range from in a range from 400 nm to 2,000 nm, such as from 500 nm to 1,000 nm, although lesser and greater thicknesses may also be employed.

An etch mask layer (not shown) can be applied over the first dielectric bonding material layer 185, and can be patterned to form first openings overlying the first topmost metal interconnect structures 148 and second openings that may optionally overlie the first topmost metal interconnect structures 148. According to an aspect of the present disclosure, the area of each first opening may be greater than the area of each second opening at least by a factor of 2, such as by a factor of 4 to 10, such as by a factor of 5 to 6. In one embodiment, each of the first openings and the second openings may have a respective horizontal cross-sectional shape of a rectangle, a rounded rectangle, or a circle.

An anisotropic etch process can be performed to form via cavities (179, 179D) in an upper portion of the first dielectric bonding material layer 185. In one embodiment, the via cavities (179, 179D) may comprise first via cavities 179 that are arranged as a two-dimensional array, which may be a two-dimensional periodic array. Each first via cavity 179 may overlie a respective one of the first topmost metal interconnect structures 148. In one embodiment, the via cavities (179, 179D) may also comprise first dummy via cavities 179D which are interlaced with the first via cavities 179. The first dummy via cavities 179D may optionally overlie a respective one of the first topmost metal interconnect structures 148.

According to an aspect of the present disclosure, the first dummy via cavities 179D may have a respective lateral extent that is less than lateral extent of each first via cavity 179. The lateral extent of each via cavity (179, 179D) may be defined as the maximum lateral dimension of the respective via cavity (179, 179D), such as the lateral dimension at the top of the respective via cavity. In one embodiment, each first via cavity 179 may have a first lateral extent, and each first dummy via cavity 179D may have a second lateral extent that is in a range from 10% to 65%, such as from 20% to 50%, of the first lateral extent. The first lateral extent may be in a range from 400 nm to 1,000 nm, such from 500 nm to 700 nm as although lesser and greater dimensions may also be employed. Thus, lateral dimension at the top of the first via cavities 179 may range from 400 nm to 1,000 nm, such from 500 nm to 700 nm, while the lateral dimension at the top of the first dummy via cavities 179D may range from 40 nm to 650 nm, such as from 50 nm to 450 nm, for example from 100 nm to 350 nm.

In one embodiment, each sidewall of a first via cavity 179 may have a first taper angle α1 relative to a vertical direction, and each sidewall of a first dummy via cavity 179D may have a second taper angle β1 relative to the vertical direction. The first taper angle α1 may be in a range from 10 degrees to 45 degrees, although lesser and greater angles may also be employed. The second taper angle β1 may be in a range from 10 degrees to 45 degrees, although lesser and greater angles may also be employed. In one embodiment, the second taper angle β1 is the same as the first taper angle α1.

As described with respect to FIG. 5D above, the etch rate of the anisotropic etch process used to form the respective via cavities (179, 179D) may be aspect-ratio-dependent. In this case, the first via cavities 179 having a lower aspect ratio are etched to greater etch depth relative to the first dummy via cavities 179D having a higher aspect ratio. Thus, the first via cavities 179 extend to the first topmost metal interconnect structures 148, and the first via cavities 179 have a greater depth than the first dummy via cavities 179D. The depth of the first via cavities 179 is the same as the thickness of the first bonding-level dielectric layer 180. In one embodiment, the depth of the first dummy via cavities 179D may be in a range from 30% to 80%, such as from 40% to 70%, of the thickness of the first bonding-level dielectric layer 180. The first via cavities 179 may have a horizontal bottom surface exposing the top surface of the first topmost metal interconnect structures 148, while the first dummy via cavities 179D may terminate in a point at the bottom. Thus, the first via cavities 179 may have a trapezoidal vertical cross-sectional shape, while the first dummy via cavities 179D may have a triangular vertical cross-sectional shape.

The anisotropic etch parameters are selected to form first and second taper angles such that a desired area of the first topmost metal interconnect structures 148 is exposed in each first via cavities 179 and such that the first dummy via cavities 179D do not extend through the entire thickness of the first bonding-level dielectric layer 180. For example, if the thickness of the first bonding-level dielectric layer 180 is 520 nm, the desired exposed width of the top surface of the first topmost metal interconnect structures 148 is 140 nm, then the width of the top of the first via cavities 179 may be 600 nm, the width of the top of the first dummy via cavities 179D may be less than 370 nm, and the etching parameters are selected to form the first taper angle α1 and the second taper angle β1 are each about 24 degrees. In other words, the angle between a horizontal surface and the sidewall of the cavities (179, 179D) is about 66 degrees.

Referring to FIGS. 10D, 10E and 10F, the steps described above with respect to FIG. 9D are performed to form the first metallic bonding structures 190 and the first dummy metallic bonding structures 190D in the respective first via cavities 179 and the first dummy via cavities 179D.

Referring to FIG. 10G, the steps described above with respect to FIG. 9E are performed to bond the first semiconductor die 100 to the second semiconductor die 200 to form the bonded assembly.

Referring to FIGS. 10A-10G, a bonded assembly of a first semiconductor die 100 and a second semiconductor die 200 is provided. The first semiconductor die 100 comprises first dielectric material layers 130 located on first semiconductor devices 120; first metal interconnect structures 140 embedded in the first dielectric material layers 130 and electrically connected to the first semiconductor devices 120; and a first bonding-level dielectric layer 180 located on the first dielectric material layers 130 and embedding first metallic bonding structures 190 that are electrically connected to a respective one of the first metal interconnect structures 140, and further embedding first dummy metallic bonding structures 190D. The first metallic bonding structures 190 have a different vertical cross-sectional shape than the first dummy metallic bonding structures 190D.

In one embodiment, the first dummy metallic bonding 190 structure has a lesser lateral extent than the first metallic bonding structure 190D. In one embodiment, the first metallic bonding structure 190 has a trapezoidal vertical cross-sectional shape and the first dummy metallic bonding structure 190 has a triangular vertical cross-sectional shape.

In one embodiment, sidewalls of the first metallic bonding structure and the first dummy metallic bonding structure are tapered, such that the first metallic bonding structure contacts a predetermined area of the one of the first metal interconnect structures, and such that the first dummy metallic bonding structure does not extend through entire thickness of the first bonding-level dielectric layer.

In one embodiment, the first metallic bonding structures 190 comprise (or may consist of) first metallic via portions; the first dummy metallic bonding structures 190D comprise (or may consist of) first dummy metallic via portions having a lesser height than the first metallic via portions; and all top peripheries of the first metallic via portions and all top peripheries of the first dummy metallic via portions are located within a horizontal plane.

In one embodiment, the first metallic bonding structures 190 have a same composition as the first dummy metallic bonding structures 190D. For example, the first metallic bonding structures 190 and the first dummy metallic bonding structures 190D each comprise a respective metallic barrier liner 190B and a respective metal fill material portion 190F.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A bonded assembly of a first semiconductor die and a second semiconductor die, wherein the first semiconductor die comprises:
first dielectric material layers located on first semiconductor devices;
first metal interconnect structures embedded in the first dielectric material layers and electrically connected to the first semiconductor devices; and
a first bonding-level dielectric layer located on the first dielectric material layers and embedding first metallic bonding structures that are electrically connected to a respective one of the first metal interconnect structures, and further embedding first dummy metallic bonding structures having a lesser vertical extent than the first metallic bonding structures and electrically isolated from the first metal interconnect structures, wherein the first metallic bonding structures have a same composition as the first dummy metallic bonding structures.

2. The bonded assembly of claim 1, wherein:
the first metallic bonding structures comprise first metallic via portions;
the first dummy metallic bonding structures comprise first dummy metallic via portions having a lesser height than the first metallic via portions; and
all top peripheries of the first metallic via portions and all top peripheries of the first dummy metallic via portions are located within a horizontal plane.

3. The bonded assembly of claim 2, wherein the first bonding-level dielectric layer comprises a stack of a first silicate glass layer and a first dielectric bonding material layer.

4. The bonded assembly of claim 3, wherein:
each of the first metallic bonding structures comprises a respective first metallic pad portion that is connected to a respective one of the first metallic via portions; and
each of the first dummy metallic bonding structures comprises a respective first dummy metallic pad portion that is connected to a respective subset of a plurality of the first dummy metallic via portions.

5. The bonded assembly of claim 4, wherein a horizontal interface between the first silicate glass layer and the first dielectric bonding material layer is located within the horizontal plane.

6. The bonded assembly of claim 4, wherein the first metallic pad portions and the first dummy metallic pad portions have a same height as a thickness of the first dielectric bonding material layer.

7. The bonded assembly of claim 4, wherein the first dielectric bonding material layer comprise a first silicon carbide nitride layer that is bonded to a second dielectric bonding material layer in the second semiconductor die via dielectric-to-dielectric bonding.

8. The bonded assembly of claim 4, wherein each of the first dummy metallic via portions has a respective maximum lateral dimension that is less than ⅓ of a maximum lateral dimension of one of the first metallic via portions.

9. The bonded assembly of claim 4, wherein the respective subset of the plurality of the first dummy metallic via portions comprises a respective two-dimensional array of first dummy metallic via portions each having a lesser maximum lateral extent than any of the first metallic via portions.

10. The bonded assembly of claim 4, wherein the respective subset of the plurality of the first dummy metallic via portions comprises a respective set of two or more first dummy metallic via portions that are nested inside one another such that each first dummy metallic via portion within the respective set of two or more first dummy metallic via portions laterally surrounds or is laterally surrounded by any other first dummy metallic via portion within the respective set of two or more first dummy metallic via portions.

11. The bonded assembly of claim 3, wherein:
the first metallic bonding structures consist of the first metallic via portions;
the first dummy metallic bonding structures consist of the first dummy metallic via portions.

12. The bonded assembly of claim 11, wherein the first dielectric bonding material layer comprises a horizontal surface located within the horizontal plane and bonded to a second dielectric bonding material layer within the second semiconductor die by dielectric-to-dielectric bonding.

13. The bonded assembly of claim 2, wherein:
the first bonding-level dielectric layer comprises a first silicate glass layer laterally surrounding first metallic via portions and the first dummy metallic via portions; and
a top surface of the first silicate glass layer is located within the horizontal plane.

14. The bonded assembly of claim 13, wherein the first silicate glass layer is bonded to a second dielectric bonding material layer within the second semiconductor die by dielectric-to-dielectric bonding.

15. A method of forming a semiconductor structure, comprising:
forming first semiconductor devices over, on or in a first substrate;
forming first metal interconnect structures embedded in first dielectric material layers over the first semiconductor devices;
forming a first bonding-level dielectric layer over the first dielectric material layers;
forming via cavities and dummy via cavities in the first bonding-level dielectric layer, wherein the via cavities vertically extend from a topmost surface of the bonding-level dielectric layer to a bottommost surface of the bonding-level dielectric layer, and the dummy via cavities have a lesser vertical extent than the via cavities; and
forming first metallic bonding structures and first dummy metallic bonding structures, wherein each of the first metallic bonding structures is formed in a respective first volume that comprises an entirety of a volume of a respective one via cavities, and each of the first dummy metallic bonding structures is formed in a respective second volume that comprises an entirety of a volume of a respective subset of a plurality of the dummy via cavities, wherein the first metallic bonding structures have a same composition as the first dummy metallic bonding structures.

16. The method of claim 15, further comprising:
forming a hard mask layer including openings therethrough over the first dielectric bonding material layer; and
performing an anisotropic etch process employing the hard mask layer as an etch mask to form the via cavities and the dummy via cavities through the first bonding-level dielectric layer.

17. The method of claim 16, wherein:
the first bonding-level dielectric layer comprising a layer stack including a first silicate glass layer and a first dielectric bonding material layer; and
the method further comprises performing a selective etch process that etches a material of the first dielectric bonding material layer selective to a material of the first silicate glass layer, whereby each of the via cavities is converted into a respective integrated pad-and-via cavities and each of the dummy via cavities is converted into a respective integrated pad-and-via cavities.

18. The method of claim 17, further comprising removing the hard mask layer prior to performing the selective etch process.

19. The method of claim 17, wherein the selective etch process is performed while the hard mask layer is present on a top surface of the first dielectric bonding material layer.

20. The method of claim 15, wherein:
the respective first volume is the same as the entirety of the volume of the respective one via cavities; and
the respective second volume is the same as the entirety of the volume of the respective subset of the plurality of the dummy via cavities.
